(19) United States
(12) Patent Application Publication
(10) Pub. No.: US 2025/0267987 A1
(43) Pub. Date: Aug. 21, 2025

(54) DEVICES INCLUDING REFLECTIVE GEOMETRIES FOR DISPLAYS AND LIGHTING APPLICATIONS

(71) Applicant: EDISON INNOVATIONS, LLC, Allen, TX (US)

(72) Inventors: James E. Murphy, Niskayuna, NY (US); Zeying Chen, Niskayuna, NY (US); Oltea P. Siclovan, Niskayuna, NY (US); Samuel Camardello, Niskayuna, NY (US)

(21) Appl. No.: 18/654,635

(22) Filed: May 3, 2024

Related U.S. Application Data
(60) Provisional application No. 63/555,346, filed on Feb. 19, 2024.

(51) Int. Cl. H01L 33/50; B60Q 1/26; C09K 11/61; H01L 33/60

(52) U.S. Cl. CPC H10H 20/8512; B60Q 1/2696; C09K 11/617; H10H 20/8515; H10H 20/856; B60Q 2400/20

(57) ABSTRACT

Devices having a reflective geometry are provided. The device includes a color conversion layer including luminescent material. The color conversion layer having a first side and a second side and a substrate having a first side and a second side. The second side of the color conversion layer located on the first side of the substrate. The device including an LED light source located remotely from the color conversion layer where the LED light source is optically coupled and/or radiationally connected to the first side of the color conversion layer. The device includes at least one of: (a) the substrate has a reflectivity of at least 20%, (b) a reflective layer located between the substrate and the color conversion layer, or (c) a back reflective layer located on the second side of the substrate. The devices are especially useful for lighting and display applications. Articles including the device are also provided.

### CROSS REFERENCE TO RELATED APPLICATIONS

This application claims priority to U.S. Provisional Patent Application Ser. No. 63/555,346 filed Feb. 19, 2024 for “DEVICES INCLUDING REFLECTIVE GEOMETRIES FOR DISPLAYS AND LIGHTING APPLICATIONS”, which is hereby incorporated by reference in its entirety.

### BACKGROUND

The subject matter described herein relates generally to devices including a light source that is optically coupled and/or radiationally connected, in a reflective geometry, to a color conversion layer deposited on a substrate. The devices are especially useful for lighting and display applications.

In many commercial LED lighting products and displays, phosphor materials and other luminescent materials are deposited directly onto an LED (e.g., in an on-chip architecture).

### BRIEF DESCRIPTION

In one aspect, a device having a reflective geometry is provided. The device includes a color conversion layer including luminescent material. The color conversion layer having a first side and a second side and a substrate having a first side and a second side. The second side of the color conversion layer located on the first side of the substrate. The device including an LED light source located remotely from the color conversion layer where the LED light source is optically coupled and/or radiationally connected to at least the first side of the color conversion layer. The device includes at least one of: (a) the substrate has a reflectivity of at least 20%, (b) a reflective layer located between the substrate and the color conversion layer, or (c) a back reflective layer located on the second side of the substrate. In some embodiments, the color conversion layer includes at least two films including luminescent material and having different refractive indices.

In another aspect, a device having a reflective geometry is provided. The device includes a color conversion layer including luminescent material. The color conversion layer having a first side and a second side and a substrate having a first side and a second side. The second side of the color conversion layer located on the first side of the substrate. The device including an LED light source located remotely from the color conversion layer where the LED light source is optically coupled and/or radiationally connected to at least the first side of the color conversion layer. The device includes at least one of: (a) the substrate has a reflectivity of at least 20%, (b) a reflective layer located between the substrate and the color conversion layer, or (c) a back reflective layer located on the second side of the substrate. In some embodiments, the color conversion layer includes at least two films including luminescent material and having different refractive indices. The luminescent material including a narrow-band emission phosphor, where the narrow-band emission phosphor includes a Mn⁴⁺ doped phosphor having formula I or a uranium-based phosphor having formula II, III, IV, V or VI:

Aₓ[MF_{y}]:Mn⁴⁺ I
wherein A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7;

[Ba_{1-a-b}SrₐCa_{b}]ₓ[Mg,Zn]_{y}(UO₂)_{z}([P,V]O₄)_{2(x+y+z)/3} II

[Ba_{1-a-b}SrₐCa_{b}]ₚ(UO₂)_{q}[P,V]ᵣO_{(2p+2q+5r)/2} III

A₂UO₂[P,V]₂O₇ IV

A₄UO₂([P,V]O₄)₂ V

AUO₂([P,V]O₃)₃ VI
wherein 0≤a≤1, 0≤b≤1, 0.75≤x≤1.25, 0.75≤y≤1.25, 0.75≤z≤1.25, 2.5≤p≤3.5, 1.75≤q≤2.25, 3.5≤r≤4.5 and A is Li, Na, K, Rb, Cs or a combination thereof.

In another aspect, a device having a reflective geometry is provided. The device includes a color conversion layer including luminescent material. The color conversion layer having a first side and a second side. A substrate having at least 20% reflectivity and a first side. The second side of the color conversion layer located on the first side of the substrate. The device including an LED light source located remotely from the color conversion layer where the LED light source is optically coupled and/or radiationally connected to at least the first side of the color conversion layer. In some embodiments, the color conversion layer includes at least two films including luminescent material and having different refractive indices.

In another aspect, a device having a reflective geometry is provided. The device includes a color conversion layer including luminescent material. The color conversion layer having a first side and a second side and a substrate having a first side. The second side of the color conversion layer located on the first side of the substrate. The device including a reflective layer located between the color conversion layer and the substrate. The device including an LED light source located remotely from the color conversion layer where the LED light source is optically coupled and/or radiationally connected to at least the first side of the color conversion layer. In some embodiments, the color conversion layer includes at least two films including luminescent material and having different refractive indices.

In another aspect, a device having a reflective geometry is provided. The device includes a color conversion layer including luminescent material. The color conversion layer having a first side and a second side and a substrate having a first side and a second side. The second side of the color conversion layer located on the first side of the substrate. The device including an LED light source located remotely from the color conversion layer where the LED light source is optically coupled and/or radiationally connected to at least the first side of the color conversion layer. The device includes a back reflective layer located on the second side of the substrate. In some embodiments, the color conversion layer includes at least two films including luminescent material and having different refractive indices.

In another aspect, a device having a reflective geometry is provided. The device includes a color conversion layer including luminescent material. The color conversion layer including at least two films having different refractive indices. The color conversion layer having a first side and a second side and a substrate having a first side. The second side of the color conversion layer located on the first side of the substrate. The device including an LED light source located remotely from the color conversion layer where the LED light source is optically coupled and/or radiationally connected to at least the first side of the color conversion layer. The device includes at least one of: (a) the substrate has a reflectivity of at least 20%, (b) a reflective layer located between the substrate and the color conversion layer, or (c) a back reflective layer located on the second side of the substrate.

In another aspect, a device having a reflective geometry is provided. The device includes a color conversion layer including a luminescent material. The color conversion layer including at least two films having different refractive indices. The films are formed by depositing two inks of two different refractive indices on a substrate layer by layer, and then drying or curing the ink to make films of two different indices. The color conversion layer having a first side and a second side and a substrate having a first side. The second side of the color conversion layer located on the first side of the substrate. The device including an LED light source located remotely from the color conversion layer where the LED light source is optically coupled and/or radiationally connected to at least the first side of the color conversion layer. The device includes at least one of: (a) the substrate has a reflectivity of at least 20%, (b) a reflective layer located between the substrate and the color conversion layer, or (c) a back reflective layer located on the second side of the substrate. In one aspect, the at least two films comprise a first film and a second film. The first film and the second films are formed by depositing two inks of two different indices on a substrate layer by layer and then drying or curing the ink to make films of two different indices. More particularly, a first ink composition having a first refractive index may be deposited on substrate and/or reflective layer. The first ink composition is cured to form the first film. The first ink composition is cured using any curing technique described herein (e.g., UV curing and/or thermal curing). Next, a second ink composition having a second refractive index may be deposited on the first film. The first and second refractive indices are different. The second ink composition may be deposited after the first ink composition has cured and formed into a film. The second ink composition is then cured using any curing technique described herein (e.g., UV curing and/or thermal curing) to from the second film. Additionally, or alternatively, the first film and the second film are remotely and/or separately formed, and one of the first film or the second film are subsequently attached to the substrate and/or reflective layer.

In another aspect, an automotive tail-light having reflective geometry is provided. The automotive tail-light includes a plurality of LED light sources and a color conversion layer comprising luminescent material, the color conversion layer having a first side and a second side. The automotive tail-light further includes a substrate having a first side, the second side of the color conversion layer located on the first side of the substrate. The plurality of LED light sources are located remotely from the color conversion layer, wherein the LED light source is optically coupled and/or radiationally connected to at least the first side of the color conversion layer. The automotive tail-light includes at least one of: (a) the substrate has a reflectivity of at least 20%, (b) a reflective layer is located between the substrate and the color conversion layer, and/or (c) a back reflective layer located on the second side of the substrate.

In another aspect, an article including any of the disclosed devices is provided. The article may comprise an illumination device, a lighting apparatus, a display apparatus, a backlight apparatus, a television, a mobile phone, a computer monitor, a laptop, a tablet computer, an automotive display, a self-emissive display, a transparent display, a windshield, an automotive light, an automotive tail-light, and/or combinations thereof.

### BRIEF DESCRIPTION OF DRAWINGS

These and other features, aspects, and advantages of the present disclosure will become better understood when the following detailed description is read with reference to the accompanying drawings in which like characters represent like parts throughout the drawings, wherein:

FIG. 1 depicts a device in accordance with one embodiment of the disclosure.

FIG. 2 depicts a device in accordance with another embodiment of the disclosure.

FIG. 3A depicts a device in accordance with another embodiment of the disclosure.

FIG. 3B depicts a device in accordance with another embodiment of the disclosure.

FIG. 4 depicts a device in accordance with another embodiment of the disclosure.

FIG. 5 depicts a device in accordance with another embodiment of the disclosure.

FIG. 6A is a schematic cross-sectional view of a matrix device in accordance with one embodiment of the disclosure.

FIG. 6B is a top planar view of the matrix device of FIG. 6A.

FIG. 7 depicts a flow diagram of an embodiment of a method in accordance with one embodiment of the disclosure.

FIG. 8 is a graph showing Total Reflectance vs Wavelength.

FIG. 9A depicts sample FR in Example 6.

FIG. 9B depicts sample FS in Example 6.

FIG. 9C depicts sample FT in Example 6.

FIG. 9D depicts sample FU in Example 6.

FIG. 10 is a graph showing CIE 1931 automotive safety color points, ccx vs ccy.

Unless otherwise indicated, the drawings provided herein are meant to illustrate features of embodiments of the disclosure. These features are believed to be applicable in a wide variety of systems comprising one or more embodiments of the disclosure. As such, the drawings are not meant to include all conventional features known by those of ordinary skill in the art to be required for the practice of the embodiments disclosed herein.

### DETAILED DESCRIPTION

In the following specification and the claims, reference will be made to a number of terms, which shall be defined to have the following meanings.

The singular forms “a”, “an”, and “the” include plural references unless the context clearly dictates otherwise. As used herein, the term “or” is not meant to be exclusive and refers to at least one of the referenced components being present and includes instances in which a combination of the referenced components may be present, unless the context clearly dictates otherwise.

Approximating language, as used herein throughout the specification and claims, may be applied to modify any quantitative representation that could permissibly vary without resulting in a change in the basic function to which it is related. Accordingly, a value modified by a term or terms, such as “about,” “substantially,” and “approximately,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

“Optional” or “optionally” means that the subsequently described event or circumstance may or may not occur, or that the subsequently identified material may or may not be present, and that the description includes instances wherein the event or circumstance occurs or wherein the material is present, and instances wherein the event or circumstance does not occur, or the material is not present.

As used herein, the terms “comprises,” “comprising,” “includes,” “including,” “has,” “having,” “contains”, “containing,” “characterized by” or any other variation thereof, are intended to cover a non-exclusive inclusion, subject to any limitation explicitly indicated. For example, a composition, mixture, process or method that comprises a list of elements is not necessarily limited to only those elements but may include other elements not expressly listed or inherent to such composition, mixture, process or method.

The transitional phrase “consisting of” excludes any element, step, or ingredient not specified. If in the claim, such would close the claim to the inclusion of materials other than those recited except for impurities ordinarily associated therewith. When the phrase “consisting of” appears in a clause of the body of a claim, rather than immediately following the preamble, it limits only the element set forth in that clause; other elements are not excluded from the claim as a whole.

The transitional phrase “consisting essentially of” is used to define a composition or method that includes materials, steps, features, components, or elements, in addition to those literally disclosed, provided that these additional materials, steps, features, components, or elements do not materially affect the basic and novel characteristic(s) of the claimed invention. The term “consisting essentially of” occupies a middle ground between “comprising” and “consisting of”.

Where an invention or a portion thereof is defined with an open-ended term such as “comprising,” it should be readily understood that (unless otherwise stated) the description should be interpreted to also describe such an invention using the terms “consisting essentially of” or “consisting of.”

As used herein, references to “example embodiment” or “one embodiment” or “some embodiments” of the present disclosure are not intended to be interpreted as excluding the existence of additional embodiments that also incorporate the recited features.

Although specific features of various embodiments of the invention may be shown in some drawings and not in others, this is for convenience only. In accordance with the principles of the invention, any feature of a drawing may be referenced and/or claimed in combination with any feature of any other drawing.

While the invention has been described in terms of various specific embodiments, those skilled in the art will recognize that the invention can be practiced with modification within the spirit and scope of the claims.

Unless otherwise indicated, the terms “first,” “second,” etc. are used herein merely as labels, and are not intended to impose ordinal, positional, or hierarchical requirements on the items to which these terms refer. Moreover, reference to, for example, a “second” item does not require or preclude the existence of, for example, a “first” or lower-numbered item or a “third” or higher-numbered item.

Square brackets in the formulas indicate that at least one of the elements is present in the phosphor material, and any combination of two or more thereof may be present. For example, the formula [Ca,Sr,Ba]₃MgSi₂O₈:Eu²⁺,Mn²⁺ encompasses at least one of Ca, Sr or Ba or any combination of two or more of Ca, Sr or Ba. Examples include Ca₃MgSi₂O₈:Eu²⁺·Mn²⁺; Sr₃MgSi₂O₈:Eu²⁺·Mn²⁺; or Ba₃MgSi₂O₈:Eu²⁺·Mn²⁺. Formula with an activator after a colon “:” indicates that the phosphor material is doped with the activator. Formula showing more than one activator separated by a “,” after a colon “:” indicates that the phosphor material is doped with either activator or both activators. For example, the formula [Ca,Sr,Ba]₃MgSi₂O₈:Eu²⁺, Mn²⁺ encompasses [Ca,Sr,Ba]₃MgSi₂O₈:Eu²⁺, [Ca,Sr,Ba]₃MgSi₂O₈:Mn²⁺ or [Ca,Sr,Ba]₃MgSi₂O₈:Eu²⁺ and Mn²⁺.

Reflectivity is a measure of the proportion of incident electromagnetic power that reflects away after striking a surface, for example blue or UV LEDs serving as the excitation source.

The term “film”, as used herein, should be understood to mean a layer of material. A film in accordance with the present disclosure may be prepared by depositing the material on a surface, such as a substrate. The term “layer”, as used herein, refers to a material disposed on at least a portion of an underlying surface in a continuous or discontinuous manner. The term “layer” does not necessarily mean a uniform thickness of the disposed material, and the disposed material may have a uniform or a variable thickness. As used herein, the term “disposed on” refers to layers or materials disposed directly in contact with each other or indirectly by having intervening layers or features there between, unless otherwise specifically indicated.

As used herein, the “curing” of a film precursor to form a film involves the solidification of the film precursor to form a film deposited on a substrate. The curing may occur via removal of solvent and/or by chemical reactions (e.g., light-based reactions). A film precursor may comprise an ink composition, an optically active material, such as a phosphor material, in an emulsion or suspension, and the like.

The term “ink composition”, as used herein, should be understood to mean a solution comprising a plurality of materials. For example, an ink composition in accordance with the present disclosure may comprise one or more of at least one optically active material (e.g., color conversion materials, such as phosphors), at least one binder material, at least one photoresist material, and/or at least one solvent. In one embodiment, an ink composition is a stable solution with the narrow band emission phosphor particles suspended and uniformly dispersed throughout the liquid composition, as disclosed in U.S. Pat. No. 11,312,876, the entire contents of each of which are incorporated herein by reference. The particulate size of the phosphor and viscosity of the ink composition affect the stability of the composition. Reducing the particulate size of the phosphor material and increasing the viscosity of the liquid composition improves the stability of the ink formulation with a very slow sedimentation rate.

D50 (also expressed as D₅₀) is defined as the median particle size for a volume distribution. D90 (also expressed as D₉₀) is the particle size for a volume distribution that is greater than the particle size of 90% of the particles of the distribution. D10 (also expressed as D₁₀) is the particle size for a volume distribution that is greater than the particle size of 10% of the particles of the distribution. Particle size of the phosphors may be conveniently measured by laser diffraction or optical microscopy methods, and commercially available software can generate the particle size distribution and span. Span is a measure of the width of the particle size distribution curve for a particulate material or powder, and is defined according to the equation:

$$Span = \frac{( {D}_{90} - {D}_{10} )}{{D}_{50}}$$

wherein D₉₀, D₁₀ and D₅₀ are defined above. For phosphor particles, span of the particle size distribution is not necessarily limited and may be ≤1.0 in some embodiments.

A “remote” LED light source indicates that the LED light source is remote in the sense that the LED light source and the color conversion layer are separate elements and that the color conversion layer is not integrated or in physical contact with the light source as a single element.

It was discovered herein that devices having a reflective geometry including a remote UV/blue LED light source that is optically coupled and/or radiationally connected to a color conversion or phosphor layer can increase the effective path length of the UV/blue light through the color conversion or phosphor layer and improve the absorption level of radiation from the remote LED light source and maximize phosphor emission in a desired direction for observation by a user. The inventors found that a reflective geometry including at least one of (a) a substrate having a reflectivity of at least 20%, (b) a substrate including a reflective layer, (c) a color conversion layer including at least two films having different refractive indices, or (d) a back reflective layer could increase the time and number of interactions between light from the LED light source and luminescent material in the color conversion layer, which consequently increases color conversion, brightness, and decreases bleed-through. As such, the devices of the present disclosure are especially useful for lighting and display applications.

In one embodiment, a device having a reflective geometry is provided. The device includes a color conversion layer including luminescent material. The color conversion layer having a first side and a second side and a substrate having a first side and a second side. The second side of the color conversion layer located on the first side of the substrate. The device including an LED light source located remotely from the color conversion layer and the LED light source is optically coupled and/or radiationally connected to at least the first side of the color conversion layer. The device includes at least one of: (a) the substrate has a reflectivity of at least 20%, (b) a reflective layer located between the substrate and the color conversion layer, (c) the color conversion layer includes at least two films having different refractive indices, and (d) a back reflective layer located on the second side of the substrate.

The color conversion layer includes luminescent material. The luminescent materials are excited and illuminated by the light emitted from the remote LED light source, such as a blue LED or UV LED. In some embodiments, the luminescent materials include phosphor materials including quantum dot material. In one embodiment, a white light blend may be obtained by blending a red phosphor material and a green phosphor material with the UV/blue light from the LED light source. The color conversion layer may include one or more other luminescent materials. Additional luminescent materials, such as blue, yellow, red, orange, or other color phosphors may be used to customize the white color of the resulting light and produce specific spectral power distributions.

In one embodiment, the luminescent material includes one or more narrow-band emission phosphors. Phosphor materials with narrow-band-emission provide wide color gamut color conversion and improved brightness in LED lighting. In one embodiment, the narrow-band emission phosphor includes a Mn⁴⁺ doped phosphor of formula I

Aₓ[MF_{y}]:Mn⁴⁺ (I)

wherein A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

The Mn⁴⁺ doped phosphors of formula I are complex fluoride materials, or coordination compounds, containing at least one coordination center surrounded by fluoride ions acting as ligands, and charge-compensated by counter ions as necessary. For example, in K₂SiF₆:Mn⁴⁺, the coordination center is Si and the counterion is K. The activator ion (Mn⁴⁺) also acts as a coordination center, substituting part of the centers of the host lattice, for example, Si. The host lattice (including the counter ions) may further modify the excitation and emission properties of the activator ion.

In particular embodiments, the coordination center of the phosphor, that is, M in formula I, is Si, Ge, Sn, Ti, Zr, Al, Ga, In, Sc, Y, La, Nb, Ta, Bi, Gd, or a combination thereof. More particularly, the coordination center may be Si, Ge, Ti, or a combination thereof. The counterion, or A in formula I, may be Li, Na, K, Rb, Cs, or a combination thereof, more particularly K or Na. Examples of phosphors of formula I include K₂[SiF₆]:Mn⁴⁺, K₂[TiF₆]:Mn⁴⁺, K₂[SnF₆]:Mn⁴⁺, Cs₂[TiF₆]:Mn⁴⁺, K₂[GeF₆]Mn⁴⁺, Rb₂[TiF₆]Mn⁴⁺, Cs₂[SiF₆]:Mn⁴⁺, Rb₂[SiF₆]:Mn⁴⁺, Na₂[SiF₆]:Mn⁴⁺, Na₂[TiF₆]:Mn⁴⁺, Na₂[ZrF₆]:Mn⁴⁺, K₃[ZrF₇]:Mn⁴⁺, K₃[BiF₆]:Mn⁴⁺, K₃[YF₆]:Mn⁴⁺, K₃[LaF₆]:Mn⁴⁺, K₃[GdF₆]:Mn⁴⁺, K₃[NbF₇]:Mn⁴⁺, K₃[TaF₇]:Mn⁴⁺. In particular embodiments, the phosphor of formula I is K₂SiF₆:Mn⁴⁺ (PFS) or Na₂[SiF₆]:Mn⁴⁺ (NSF).

The amount of activator Mn incorporation in the Mn⁴⁺ doped phosphors (referred to as Mn %) improves color conversion. Increasing the amount of Mn % incorporation improves color conversion by increasing the intensity of the red emission, maximizing absorption of excitation blue light and reducing the amount of unconverted blue light or bleed-through of blue light from a blue emitting LED.

In one embodiment, the red-emitting Mn⁴⁺ doped phosphor has a Mn loading or Mn % of at least 1 wt %. In one embodiment, the red-emitting phosphor has a Mn loading of at least 1.4 wt %. In another embodiment, the red-emitting phosphor has a Mn loading of at least 1.5 wt %. In another embodiment, the red-emitting phosphor has a Mn loading of at least 1.7 wt %. In another embodiment, the red-emitting phosphor has a Mn loading of at least 2 wt %. In another embodiment, the red-emitting phosphor has a Mn % of at least 3 wt %. In another embodiment the Mn % is greater than 2.0 wt %. In another embodiment, the content of Mn in the red-emitting phosphor is from about 1 wt % to about 4 wt %. In another embodiment, the red-emitting phosphor has a Mn % from about 2 wt % to about 5 wt %. In another embodiment, the phosphor has a Mn % from about 1.4 wt % to about 4 wt % or from about 1.4 wt % to about 3 wt %. In another embodiment, the phosphor has a Mn % from about 2 wt % to about 3 wt %.

In another embodiment, the red-emitting Mn⁴⁺ doped phosphor has a Mn loading from about 1.2 mol % based on total mol % of Mn and M (from formula I) to about 21 mol %, particularly from about 1.2 mol % to about 16.5 mol %. In particular embodiments, the amount of Mn may range from about 2 mol % to about 13.4 mol %, or from about 2 mol % to about 12.2 mol %, or from about 2 mol % to about 11.2 mol %, or from about 2 mol % to about 10 mol %, or from about 2 mol % to about 5.5 mol %, or from about 2 mol % to about 3.0 mol %.

In one embodiment, the Mn⁴⁺ doped phosphor may be a manganese-doped potassium fluorosilicate, such as K₂SiF₆:Mn⁴⁺ (also known as PFS or KSF). PFS has a peak emission centered around 631 nm and contains about 5 emission peaks, each of which are less than 2 nm full width at half maximum (FWHM).

In one embodiment, Mn⁴⁺ doped phosphors may be further treated, such as by annealing, wash treatment, roasting or any combination of these treatments. Post-treatment processes for Mn⁴⁺ doped phosphors are described in U.S. Pat. Nos. 8,906,724, 8,252,613, 9,698,314, US Publication No. 2016/0244663, US Publication No. 2018/0163126, and US Publication No. 2020/0369956, the entire contents of each of which are incorporated herein by reference. In one embodiment, the Mn⁴⁺ doped phosphors may be annealed, treated with multiple wash treatments, and roasted.

To improve reliability, the Mn⁴⁺ doped phosphor of Formula I may be at least partially coated with surface coatings to enhance stability of the phosphor particles and resist aggregation by modifying the surface of the particles and increase the zeta potential of the particles. In one embodiment, the surface coatings may be a metal fluoride, silica or organic coating. In one embodiment, the red-emitting phosphors based on complex fluoride materials activated by Mn⁴⁺ phosphors are at least partially coated with a metal fluoride, which increases positive Zeta potential and reduces agglomeration. In one embodiment, the metal fluoride coating includes MgF₂, CaF₂, SrF₂, BaF₂, AgF, ZnF₂, AlF₃ or a combination thereof. In another embodiment, the metal fluoride coating is in an amount from about 0.1 wt % to about 10 wt %. In another embodiment, the metal fluoride coating is present in an amount from about 0.1 wt % to about 5 wt %. In another embodiment, the metal fluoride coating is present from about 0.3 wt % to about 3 wt %. Metal fluoride coated red-emitting phosphors based on complex fluoride materials activated by Mn⁴⁺ are prepared as described in WO 2018/093832, US Publication No. 2018/0163126 and US Publication No. 2020/0369956, the entire contents of each of which are incorporated herein by reference.

In some embodiments, the Mn⁴⁺ doped phosphor of Formula I has a D50 particle size less than 30 μm, less than 15 μm, less than 10 μm, particularly less than 8 μm, particularly 4-8 μm, or nano-sized.

In another embodiment, the narrow-band emission phosphor includes a uranium-based phosphor. In one embodiment, the uranium-based phosphor has formula II, III, IV, V or VI:

[Ba_{1-a-b}SrₐCa_{b}]ₓ[Mg,Zn]_{y}(UO₂)_{z}([P,V]O₄)_{2(x+y+z)/3} II

[Ba_{1-a-b}SrₐCa_{b}]ₚ(UO₂)_{q}[P,V]ᵣO_{(2p+2q+5r)/2} III

A₂UO₂[P,V]₂O₇ IV

A₄UO₂([P,V]O₄)₂ V

AUO₂([P,V]O₃)₃ VI

where 0≤a≤1, 0≤b≤1, 0.75≤x≤1.25, 0.75≤y≤1.25, 0.75≤z≤1.25, 2.5≤p≤3.5, 1.75≤q≤2.25, 3.5≤r≤4.5 and A is Li, Na, K, Rb, Cs or a combination thereof.

Uranium-based phosphors herein may be characterized as uranium-based or U-doped because the U⁶⁺ ions are part of the emitting species. The term U-doped typically indicates that a relatively small number of uranium atoms is substituted in the host lattice. In many compounds, the uranium is present in the host lattice as the uranyl ion (UO₂)²⁺. Because the uranyl ion is characterized by linear O—U—O bonding, there is typically an upper limit to the substitution that can be achieved, on the order of a few mole percent with respect to the site on which it is substituted. When substituted for an M²⁺ ion there are size constraints between the M²⁺ and the (UO₂)²⁺ center that may create host lattice strain and/or compensating defects in the host lattice. As a result, concentration quenching of the U⁶⁺ emission usually occurs before full substitution is achieved. In contrast, the phosphors of the present disclosure contain the UO₂ species as part of the host lattice and comprise uranyl ions at a concentration as high as about 40 mole % relative to the total number of moles of M²⁺ cations present.

In some embodiments, the uranium-based phosphors are doped with one or more additional activator ions. A small number of the activator ions are incorporated into the host lattice of the compound. The activator ions may be Mn²⁺, Mn⁴⁺, Ce³⁺, Cr³⁺, Eu²⁺, Eu³⁺, Sn²⁺, Bi³⁺, Sb³⁺, Tb³⁺, Ti⁴⁺, In⁺, Tl⁺, Dy³⁺, Pb²⁺ or lanthanide ions. In some embodiments, the activator ions are Eu³⁺, Pr³⁺ or Sm³⁺ including mixtures of Eu³⁺, Pr³⁺ or Sm³⁺.

In some embodiments, the uranium-based phosphors may include activator ions in an amount of from about 0.001 to about 10 mole percent. In another embodiment, the activator ions may be present in an amount of from about 0.01 mole percent to about 10 mole percent. In another embodiment, the activator ion may be present in an amount from about 0.1 mole percent to about 10 mole percent. In another embodiment, the activator ion may be present in an amount from about 0.5 mole percent to about 5 mole percent. In another embodiment, the activator ion may be present from about 1 mole percent to about 3 mole percent. In another embodiment, the activator ion may be present from about 0.01 mole percent to about 1 mole percent. In another embodiment, the activator ion may be present from about 0.05 mole percent to about 1 mole percent. In another embodiment, the activator ion may be present from about 0.1 mole percent to about 1 mole percent. In another embodiment, the activator ion may be present from about 0.5 mole percent to about 1 mole percent.

In some embodiments, the uranium-based phosphors are doped with counter ions. A small number of the counter ions are incorporated into the host lattice of the compound. In one embodiment, the counter ions may be one or more alkali metal ions. The alkali metal ions may be Li⁺, K⁺, Na⁺, Rb⁺, Cs⁺ or mixtures of the alkali metal ions.

In one embodiment, the counter ion may be present in an amount from about 0.01 mole percent to about 10 mole percent. In another embodiment, the counter ions may be present in an amount of from about 0.1 mole percent to about 10 mole percent. In another embodiment, the counter ion may be present in an amount from about 0.5 mole percent to about 5 mole percent. In another embodiment, the counter ion may be present from about 1 mole percent to about 3 mole percent. In another embodiment, the counter ion may be present from about 0.01 mole percent to about 1 mole percent. In another embodiment, the counter ion may be present from about 0.05 mole percent to about 1 mole percent. In another embodiment, the counter ion may be present from about 0.1 mole percent to about 1 mole percent. In another embodiment, the counter ion may be present from about 0.5 mole percent to about 1 mole percent.

In one embodiment, the uranium-based phosphor has formula II. In some embodiments, uranium-based phosphors having formula II may include one or more activator ions. In one embodiment, the activator ions may be Eu³⁺, Pr³⁺ or Sm³⁺. In another embodiment, uranium-based phosphors of formula II may include counter ions. The counter ions may be alkali metals. In some embodiments, the alkali metals may be Li⁺, Na⁺, K⁺, Rb⁺, Cs⁺, or mixtures thereof. Uranium-based phosphors may have Formula II with an activator ion and a counter ion. In another embodiment, the uranium-based phosphor has Formula II with one or more activator ions Eu³⁺, Pr³⁺, or Sm³⁺ and with one or more alkali metal counter ions.

In some embodiments, phosphors of formula II may contain phosphate groups and have formula Baₓ[Mg,Zn]_{y}(UO₂)_{z}[PO₄]_{2(x+y+z)/3}. Particular examples include Ba[Mg,Zn]UO₂(PO₄)₂, and more particularly BaMgUO₂(PO₄)₂ and BaZnUO₂(PO₄)₂.

In one embodiment, the uranium-based phosphor has formula III. In some embodiments, phosphors of formula III may contain phosphate or pyrophosphate groups and have formula Baₚ(UO₂)_{q}PᵣO_{(2p+2q+5r)/2}. In some embodiments, the uranium-based phosphors have formula IIIA: [Ba,Sr,Ca,Mg,Zn]ₚ(UO₂)_{q}[P,V]ᵣO_{(2p+2q+5r)/2}, where 2.5≤p≤3.5, 1.75≤q≤2.25 and 3.5≤r≤4.5. In some embodiments, Formula III and Formula IIIA exclude the combination where a is 0, b is 0, p is 3.5, q is 1.75 and r is 3.5.

In some embodiments, uranium-based phosphors having formula III or IIIA may include one or more activator ions. In one embodiment, the activator ions may be Eu³⁺, Pr³⁺ or Sm³⁺. In another embodiment uranium-based phosphors of formula III or IIIA may include counter ions. The counter ions may be alkali metals. In some embodiments, the alkali metals may be Li⁺, Na⁺, K⁺, Rb⁺, Cs⁺, or mixtures thereof. Uranium-based phosphors may have Formula III or IIIA with an activator ion and a counter ion. In another embodiment, the uranium-based phosphor has Formula III or IIIA with one or more activator ions Eu³⁺, Pr³⁺, or Sm³⁺ and with one or more alkali metal counter ions.

Particular examples of the uranium-based phosphors having Formula III or IIIA include Ba₃(PO₄)₂(UO₂)₂P₂O₇, Ba₃(PO₄)₂(UO₂)₂V₂O₇ and gamma-phase Ba₂UO₂(PO₄)₂ (“γ-Ba₂UO₂(PO₄)₂”). (Phosphor gamma-phase Ba₂UO₂(PO₄)₂ is described in PCT Publication No. WO 2021/211600, which is incorporated herein by reference.) In one embodiment, the phosphor may be γ-Ba₂UO₂(PO₄)₂:Eu³⁺ or Ba₃(PO₄)₂(UO₂)₂P₂O₇:Eu³⁺.

In other embodiments, the uranium-based phosphors have formula IV. In some embodiments, uranium-based phosphors having formula IV may include one or more activator ions. In one embodiment, the activator ions may be Eu³⁺, Pr³⁺ or Sm³⁺. Particular examples include A₂UO₂P₂O₇, and more particularly, Na₂UO₂P₂O₇, K₂UO₂P₂O₇, Rb₂UO₂P₂O₇, or Cs₂UO₂P₂O₇ and/or Na₂UO₂P₂O₇:Eu³⁺.

In other embodiments, the uranium-based phosphors have formula V. Particular examples include K₄UO₂(PO₄)₂ or K₄UO₂(VO₄)₂.

In other embodiments, the uranium-based phosphors have formula VI. In one embodiment, the uranium-based phosphor may be NaUO₂P₃O₉.

In one embodiment, the uranium-based phosphors may be BaMgUO₂(PO₄)₂, BaZnUO₂(PO₄)₂, Ba₃(PO₄)₂(UO₂)₂P₂O₇, gamma-phase Ba₂UO₂(PO₄)₂ (“γ-Ba₂UO₂(PO₄)₂”), Ba₂Sr(PO₄)₂(UO₂)₂P₂O₇, BaSr₂(PO₄)₂(UO₂)₂P₂O₇, Sr₃(PO₄)₂(UO₂)₂P₂O₇, Ca₃(PO₄)₂(UO₂)₂P₂O₇, BaMg₂(PO₄)₂(UO₂)₂P₂O₇, Ba₂Mg(PO₄)₂(UO₂)₂P₂O₇, Na₂UO₂P₂O₇, K₂UO₂P₂O₇, Ba₂UO₂(VO₄)₂, Rb₂UO₂P₂O₇, Cs₂UO₂(VO₄)₂, KUO₂(PO₄)₂, or NaUO₂P₃O₉.

In some embodiments, the uranium-based phosphors are Na₂UO₂P₂O₇, Rb₂UO₂P₂O₇, K₂UO₂P₂O₇, Cs₂UO₂P₂O₇, NaUO₂P₃O₉, K₄UO₂(PO₄)₂, Ba₃(PO₄)₂(UO₂)₂P₂O₇, BaZnUO₂(PO₄)₂, γ-Ba₂UO₂(PO₄)₂, Na₂UO₂P₂O₇ doped with Eu³⁺, Na₂UO₂P₂O₇ doped with Pr³⁺, Na₂UO₂P₂O₇ doped with Sm³⁺, Na₂UO₂P₂O₇ doped with Eu³⁺ and Pr³⁺, Na₂UO₂P₂O₇ doped with Eu³⁺ and Sm³⁺, K₂UO₂P₂O₇ doped with Eu³⁺, K₂UO₂P₂O₇ doped with Pr³⁺, K₂UO₂P₂O₇ doped with Sm³⁺, NaUO₂P₃O₉ doped with Eu³⁺, K₄UO₂(PO₄)₂ with Eu³⁺, Ba₃(PO₄)₂(UO₂)₂P₂O₇ with Eu³⁺, Ba₃(PO₄)₂(UO₂)₂P₂O₇ with Pr³⁺, Ba₃(PO₄)₂(UO₂)₂P₂O₇ with Sm³⁺, Ba₃(PO₄)₂(UO₂)₂P₂O₇ with Eu³⁺ and K⁺, Ba₃(PO₄)₂(UO₂)₂P₂O₇ with Pr³⁺ and K⁺, Ba₃(PO₄)₂(UO₂)₂P₂O₇ with Sm³⁺ and K⁺, BaZnUO₂(PO₄)₂ with Eu³⁺, BaZnUO₂(PO₄)₂ with Pr³⁺, BaZnUO₂(PO₄)₂ with Sm³⁺, BaZnUO₂(PO₄)₂ with Eu³⁺ and K⁺, BaZnUO₂(PO₄)₂ with Eu³⁺ and Li⁺, BaZnUO₂(PO₄)² with Pr³⁺ and K⁺, BaZnUO₂(PO₄)² with Sm³⁺ and K⁺, γ-Ba₂UO₂(PO₄)₂ with Eu³⁺, γ-Ba₂UO₂(PO₄) with Pr³⁺, γ-Ba₂UO₂(PO₄)₂ with Sm³⁺, γ-Ba₂UO₂(PO₄)₂ with Eu³⁺ and K⁺, γ-Ba₂UO₂(PO₄)₂ with Pr³⁺ and K⁺, γ-Ba₂UO₂(PO₄)₂ with Sm³⁺ and K⁺, Rb₂UO₂P₂O₇ with Eu³⁺, Rb₂UO₂P₂O₇ with Pr³⁺, Rb₂UO₂P₂O₇ with Sm³⁺, Cs₂UO₂P₂O₇ with Eu³⁺, Cs₂UO₂P₂O₇ with Pr³⁺, Cs₂UO₂P₂O₇ with Sm³⁺.

In one embodiment, uranium-based phosphors having formula II, III, IIIA or IV include one or more activator ions. In another embodiment, the uranium-based phosphors having formula II, III, IIIA or IV are doped with Eu³⁺, Pr³ or Sm³⁺ or mixtures of the activator ions. Uranium-based phosphors doped with Eu³⁺, Pr^{3:} or Sm³⁺ have tunable emission spectra based on the amount of activator ion added to the host compositions.

The uranium-based phosphors of the present disclosure may be produced by firing a mixture of precursors under an oxidizing atmosphere. Non-limiting examples of suitable precursors include the appropriate metal oxides, hydroxides, alkoxides, carbonates, nitrates, aluminates, silicates, citrates, oxalates, carboxylates, tartrates, stearates, nitrites, peroxides, phosphates, pyrophosphates, alkali salts and combinations thereof. Suitable materials for use as precursors include, but are not limited to, BaCO₃, BaHPO₄, Ba₃(PO₄)₂, Ba₂P₂O₇, Ba₂Zn(PO₄)₂, BaZnP₂O₇, Ba(OH)₂, Ba(C₂O₄), Ba(C₂H₃O₂)₂, Ba₃(C₆H₅O₇)₂, Ba(NO₃)₂, CaCO₃, Cs₂CO₃, KH₂PO₄, K₂HPO₄, K₂CO₃, Li₂CO₃, LiH₂PO₄, Li₂HPO₄, Mg(C₂O₄), Mg(C₂H₃O₂)₂, Mg(C₆H₆O₇), MgCO₃, MgO, Mg(OH)₂, Mg₃(PO₄)₂, Mg₂P₂O₇, Mg₂Ba(PO₄)₂, MgHPO₄, Mg(NO₃)₂, NaH₂PO₄, Na₂HPO₄, Na₂CO₃, NH₄MgPO₄, (NH₄)₂HPO₄, NH₄VO₃, RbCO₃, SrCO₃, Zn(C₂O₄), Zn(C₂H₃O₂)₂, Zn₃(C₆H₅O₇)₂, ZnCO₃, ZnO, Zn(OH)₂, Zn₃(PO₄)₂, Zn₂P₂O₇, Zn₂Ba(PO₄)₂, ZnHPO₄, Zn(NO₃)₂, NH₄ZnPO₄, UO₂, UO₂(NO₃)₂, (UO₂)₂P₂O₇, (UO₂)₃(PO₄)₂, NH₄UO₂PO₄, UO₂CO₃, UO₂(C₂H₃O₂)₂, UO₂(C₂O₄), HUO₂PO₄, HUO₂PO₄-4H₂O, UO₂(OH)₂ and ZnUO₂(C₂H₃O₂)₄, and various hydrates. For example, the exemplary phosphor BaMgUO₂(PO₄) 2 may be produced by mixing the appropriate amounts of BaCO₃, MgO and UO₂ with the appropriate amount of (NH₄)₂HPO₄ and then firing the mixture under an air atmosphere. The exemplary phosphor BaZnUO₂(PO₄)₂ may be produced by mixing appropriate amounts of BaCO₃, ZnO and UO₂ with appropriate amount of DAP and then firing the mixture under an air atmosphere. In another example, the exemplary gamma barium uranyl phosphate or gamma barium uranyl ortho-phosphate (γ-Ba₂UO₂(PO₄)₂) may be produced by mixing stoichiometric amounts of BaHPO₄ and UO₂ with an excess of (NH₄)₂HPO₄ (DAP) and then firing the mixture under an air atmosphere. The precursors may be in solid form or in solution. Non-limiting of solvents include water, ethanol, acetone, and isopropanol, and suitability depends chiefly on solubility of the precursors in the solvent. After firing, the phosphor may be milled to break up any agglomerates that may have formed during the firing procedure. The phosphors may be ground or milled, in a conventional manner, into smaller particle sizes, as desired.

The mixture of starting materials may include activator precursor oxide materials, such as Eu₂O₃, Sm₂O₃ or Pr₆O₁₁ and precursor phosphate materials, such as EuPO₄, SmPO₄ or PrPO₄. The mixture of starting materials for producing the phosphor may also include one or more low melting temperature flux materials, such as boric acid, borate compounds such as lithium tetraborate, alkali phosphates, and combinations thereof. Non-limiting examples include DAP, Li₃PO₄, Na₃PO₄, NaBO₃—H₂O, Li₂B₄O₇, K₄P₂O₇, Na₄P₂O₇, H₃BO₃ and B₂O₂. The flux may lower the firing temperature and/or firing time for the phosphor. If a flux is used, it may be desirable to wash the final phosphor product with a suitable solvent to remove any residual soluble impurities that may have originated from the flux.

The firing of the samples is generally done in air, but since the uranium is in its highest oxidation state (U⁶⁺) it can also be fired in O₂ or other wet or dry oxidizing atmospheres, including at oxygen partial pressures above one atmosphere, at a temperature between about 900° C. and about 1300° C., particularly between about 1000° C. and about 1200° C., for a time sufficient to convert the mixture to the phosphor. The firing time required may range from about one to twenty hours, depending on the amount of the mixture being fired, the extent of contact between the solid and the gas of the atmosphere, and the degree of mixing while the mixture is fired or heated. The mixture may rapidly be brought to and held at the final temperature at a lower rate as from about 2° C./minute to about 200° C./minute.

In some embodiments, the luminescent material includes a combination of a narrow band red-emitting phosphor and a narrow band green-emitting phosphor. In one embodiment, the narrow band red-emitting phosphor includes a Mn⁴⁺ doped phosphor having formula I and the narrow-band green-emitting phosphor is a uranium-based phosphor. In another embodiment, the narrow band red-emitting phosphor may be K₂SiF₆:Mn⁴⁺ (PFS) or Na₂[SiF₆]:Mn⁴⁺ (NSF) and the narrow-band green-emitting phosphor may be Ba₃(PO₄)₂(UO₂)₂P₂O₇, Ba₃(PO₄)₂(UO₂)₂V₂O₇, γ-Ba₂UO₂(PO₄)₂, BaMgUO₂(PO₄)₂, BaZnUO₂(PO₄)₂, Na₂UO₂P₂O₇, K₂UO₂P₂O₇, Rb₂UO₂P₂O₇, Cs₂UO₂P₂O₇, K₄UO₂(PO₄)₂. K₄UO₂(VO₄)₂, or NaUO₂P₃O₉.

In another embodiment, both the narrow band red-emitting phosphor and the narrow-band green-emitting phosphor are uranium-based phosphors. In one embodiment, the narrow band red-emitting phosphor may be Na₂UO₂P₂O₇:Eu³⁺ and the narrow-band green-emitting phosphor may be Ba₃(PO₄)₂(UO₂)₂P₂O₇, Ba₃(PO₄)₂(UO₂)₂V₂O₇, Y—Ba₂UO₂(PO₄)₂, BaMgUO₂(PO₄)₂, BaZnUO₂(PO₄)₂, Na₂UO₂P₂O₇, K₂UO₂P₂O₇, Rb₂UO₂P₂O₇, Cs₂UO₂P₂O₇, K₄UO₂(PO₄)₂. K₄UO₂(VO₄)₂, or NaUO₂P₃O₉.

In one embodiment, the luminescent materials include rare earth garnet phosphors. The rare earth elements include: Sc, Y, La, Ce, Pr, Nd, Pm, Sm, Eu, Gd, Tb, Dy, Ho, Er, Tm, Yb and Lu. In one embodiment, the rare earth Garnet phosphor is an yttrium aluminum garnet phosphor (YAG).

In some embodiments, the luminescent material includes a blend of the Mn⁴⁺ doped phosphor having formula I and a rare earth garnet phosphor. The ratio of the rare earth garnet phosphors to Mn⁴⁺ doped phosphors may be tuned to reach a desired color point. In further embodiments, the phosphor blend of Mn⁴⁺ doped phosphor and rare earth garnet phosphor has a high percentage of the rare earth Garnet phosphor. In some embodiments, the rare earth Garnet phosphor may be present in the phosphor blend in an amount of about 60 wt % to about 90 wt % and the Mn⁴⁺ doped phosphor may be present from about 40 wt % to about 10 wt %. In another embodiment, the rare earth Garnet phosphor may be present in the phosphor blend in an amount of about 80 wt % to about 99.9 wt %. Additionally, the Mn⁴⁺ doped phosphor may be present in the phosphor material in an amount of about 20 wt % to about 0.1 wt %. In some embodiments, the rare earth Garnet phosphor may be present in the phosphor material in an amount of about 90 wt % to about 99.9 wt %. Additionally, the Mn⁴⁺ doped phosphor may be present in the phosphor material in an amount of about 10 wt % to about 0.1 wt %. In some embodiments, the rare earth Garnet phosphor may be present in the phosphor material in an amount of about 95 wt % to about 99.9 wt %. Additionally, the Mn⁴⁺ doped phosphor may be present in the phosphor material in an amount of about 5 wt % to about 0.1 wt %. The wt % of the phosphor material is based on the total weight of the phosphor blend of the rare earth garnet phosphor and the Mn⁴⁺ doped phosphor. In some embodiments, the rare earth Garnet phosphor comprises YAG and the Mn⁴⁺ doped phosphor comprises PFS. In another embodiment, the luminescent material comprises yttrium aluminum garnet (YAG) and K₂SiF₆:Mn⁴⁺ (PFS).

Additional luminescent materials, such as blue, yellow, red, orange, or other color phosphors may be used in the color conversion layer to customize the white color of the resulting light and produce specific spectral power distributions. In one embodiment, a white light blend may be obtained by blending a red phosphor material and a green phosphor material with a light source, such as a blue LED or UV LED.

Suitable phosphors for use in the color conversion layer, include, but are not limited to: ((Sr_{1-z}[Ca,Ba,Mg,Zn]_{z})_{1-(x+w)}[Li,Na,K,Rb]_{w}Ceₓ)₃(Al_{1-y}Si_{y})O_{4+y+3(x-w)}F_{1-y-3(x-w)}, 0<x≤0.10, 0≤y≤0.5, 0≤z≤0.5, 0≤w≤x; [Ca,Ce]₃Sc₂Si₃O₁₂ (CaSiG); [Sr,Ca,Ba]₃Al₁₋ₓSiₓO₄₊ₓF₁₋ₓ:Ce³⁺ (SASOF)); [Ba,Sr,Ca]₅(PO₄)₃[Cl,F,Br,OH]:Eu²⁺, Mn²⁺; [Ba,Sr,Ca]BPO₅:Eu²⁺, Mn²⁺; [Sr,Ca]₁₀(PO₄)₆*vB₂O₃:Eu²⁺ (wherein 0<v≤1); Sr₂Si₃O₈*2SrCl₂:Eu²⁺; [Ca,Sr,Ba]₃MgSi₂O₈:Eu²⁺, Mn²⁺; BaAl₈O₁₃:Eu²⁺; 2SrO*0.84P₂O₅*0.16B₂O₃:Eu²⁺; [Ba,Sr,Ca]MgAl₁₀O₁₇:Eu²⁺,Mn²⁺; [Ba,Sr,Ca]Al₂O₄:Eu²⁺; [Y,Gd,Lu,Sc,La]BO₃:Ce³⁺,Tb³⁺; ZnS:Cu⁺,Cl⁻; ZnS:Cu⁺,Al³⁺; ZnS:Ag⁺,Cl⁻; ZnS:Ag⁺,Al³⁺; [Ba,Sr,Ca]₂Si₁₋ₙO₄₋₂ₙ:Eu²⁺ (wherein 0≤n≤0.2); [Ba,Sr,Ca]₂[Mg,Zn]Si₂O₇:Eu²⁺; [Sr,Ca,Ba][Al,Ga,In]₂S₄:Eu²⁺; [Y,Gd,Tb,La,Sm,Pr,Lu]₃[Al,Ga]₅₋ₐO_{12-3/2a}:Ce³⁺ (wherein 0≤a≤0.5); [Ca,Sr]₈[Mg,Zn](SiO₄)₄Cl₂:Eu²⁺,Mn²⁺; Na₂Gd₂B₂O₇:Ce³⁺,Tb³⁺; [Sr,Ca,Ba,Mg,Zn]₂P₂O₇:Eu²⁺,Mn²⁺; [Gd,Y,Lu,La]₂O₃:Eu³⁺,Bi³⁺; [Gd,Y,Lu,La]₂O₂S:Eu³⁺,Bi³⁺; [Gd,Y,Lu,La]VO₄:Eu³⁺,Bi³⁺; [Ca,Sr,Mg]S:Eu²⁺,Ce³⁺; SrY₂S₄:Eu²⁺; CaLa₂S₄:Ce³⁺; [Ba,Sr,Ca]MgP₂O₇:Eu²⁺,Mn²⁺; [Y,Lu]₂WO₆:Eu³⁺,Mo⁶⁺; [Ba,Sr,Ca]_{b}Si_{g}Nₘ:Eu²⁺ (wherein 2b+4g=3m); Ca₃(SiO₄)Cl₂:Eu²⁺; [Lu,Sc,Y,Tb]₂₋ᵤ₋ᵥCeᵥCa₁₊ᵤLi_{w}Mg_{2-w}P_{w}[Si,Ge]_{3-w}O_{12-u/2} (wherein 0.5≤u≤1, 0<v≤0.1, and 0≤w≤0.2); [Y,Lu,Gd]₂₋ₘ [Y,Lu,Gd]CaₘSi₄N₆₊ₘC₁₋ₘ:Ce³⁺, (wherein 0≤m≤0.5); [Lu,Ca,Li,Mg,Y], alpha-SiAlON doped with Eu²⁺ and/or Ce³⁺; Sr(LiAl₃N₄):Eu²⁺, [Ca,Sr,Ba]SiO₂N₂:Eu²⁺,Ce³⁺; beta-SiAlON:Eu²⁺; 3.5MgO*0.5MgF₂*GeO₂:Mn⁴⁺; Ca_{1-c-f}Ce_{c}Eu_{f}Al_{1+c}Si_{1-c}N₃, (wherein 0≤c≤0.2, 0≤f≤0.2); Ca₁₋ₕ₋ᵣCeₕEuᵣAl₁₋ₕ(Mg,Zn)ₕSiN₃, (wherein 0≤h≤0.2, 0≤r≤0.2); Ca₁₋₂ₛ₋ₜCeₛ[Li,Na]ₛEuₜAlSiN₃, (wherein 0≤s≤0.2, 0≤t≤0.2, s+t>0); [Sr,Ca]AlSiN₃; and Eu²⁺, Ce³⁺, Li₂CaSiO₄:Eu²⁺.

In particular embodiments, suitable phosphors include: [Y,Gd,Lu,Tb]₃[Al,Ga]₅O₁₂:Ce³⁺, β-SiAlON, β-SiAlON:Eu²⁺, [Sr,Ca,Ba][Ga,Al]₂S₄:Eu²⁺, [Li,Ca]α-SiAlON:Eu²⁺, [Ba,Sr,Ca]₂Si₅N₈:Eu²⁺, [Ca,Sr]AlSiN₃:Eu²⁺, [Ba,Sr,Ca]LiAl₃N₄:Eu²⁺, [Sr,Ca,Mg]S:Eu²⁺, and [Ba,Sr,Ca]₂Si₂O₄:Eu²⁺.

Phosphors may have particle sizes in any desired size. In one embodiment, phosphors, including narrow-band emission phosphors, has a D50 particle size less than 20 μm, less than 15 μm, less than 10 μm, particularly less than 5 μm, more particularly nano-sized. In another embodiment, the D50 particle size may be from about 1 micron to about 20 microns. In another embodiment, the D50 particle size is from about 1 micron to about 15 microns. In another embodiment, the D50 particle size is from about 1 micron to about 10 microns. In another embodiment, the D50 particle size is from about 1 micron to about 5 microns. In another embodiment, the D50 particle size is from about 1 micron to about 3 microns. In another embodiment, the D50 particle size is from about 50 nm to about 1000 nm. In another embodiment, the D50 particle size is from about 100 nm to about 1000 nm. In another embodiment, the D50 particle size is from about 200 nm to about 1000 nm. In another embodiment, the D50 particle size is from about 250 nm to about 1000 nm. In another embodiment, the D50 particle size is from about 500 nm to about 1000 nm. In another embodiment, the D50 particle size is from about 750 nm to about 1000 nm. In another embodiment, the D50 particle size is from about 50 nm to about 10 microns. In another embodiment, the D50 particle size is from about 200 nm to about 5 microns. In another embodiment, the D50 particle size is from about 250 nm to about 5 microns. In another embodiment, the D50 particle size is from about 500 nm to about 5 microns. In another embodiment, the D50 particle size is from about 750 nm to about 5 microns. In another embodiment, the D50 particle size is from about 750 nm to about 3 microns. In another embodiment, the D50 particle size is from about 0.1 microns to about 15 microns.

In some embodiments, phosphors have a D50 particle size from about 0.5 microns to about 15 microns. In some embodiments, phosphors have a D50 particle size from about 0.5 microns to about 10 microns. In some embodiments, phosphors have a D50 particle size from about 0.1 microns to about 5 microns. In some embodiments, narrow-band emission phosphors have a D50 particle size from about 0.5 microns to about 15 microns. In some embodiments, narrow-band emission phosphor has a D50 particle size from about 0.5 microns to about 10 microns. In some embodiments, narrow-band emission phosphors have a D50 particle size from about 0.1 microns to about 5 microns. In some embodiments, rare earth Garnet phosphors have a D50 particle size in a range from about 0.5 to about 15 microns. In another embodiment, rare earth Garnet phosphor has a D50 particle size in a range from about 0.5 micron to about 10 microns. In another embodiment, rare earth Garnet phosphors has a D50 particle size in a range from about 0.1 micron to about 5 microns.

In some embodiments, the luminescent material includes quantum dot material. Exemplary QD materials include, but are not limited to, group II-IV compound semiconductors such as CdS, CdSe, CdS/ZnS, CdSe/ZnS or CdSe/CdS/ZnS, group II-VI, such as CdTe, ZnSe, ZnTe, ZnS, HgTe, HgS, HgSe, CdSeTe, CdSTe, ZnSeS, ZnSeTe, ZnSTe, HgSeS, HgSeTe, HgSTe, CdZnS, CdZnSc, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, HgZnSTe, group III-V or group IV-VI compound semiconductors such as GaN, GaP, GaNP, GaNAs, GaPAs, GaAs, GaAlNP, GaAlNAs, GaAlPAs, GaInNP, GaInNAs, GaInPAs, AlN, AlNP, AlNAs, AlP, AlPAs, AlAs, InN, InNP, InP, InNAs, InPAs, InAS, InAlNP, InAlNAs, InAlPAs, PbS/ZnS or PbSe/ZnS, group IV, such as Si, Ge, SiC, and SiGe, chalcopyrite-type compounds, including, but not limited to, CuInS₂, CuInSe₂, CuGaS₂, CuGaSe₂, AgInS₂, AgInSe₂, AgGaS₂, AgGaSe₂ or perovskite QDs having a formula of ABX₃ wherein A is cesium, methylammonium or formamidinium, B is lead or tin and C is chloride, bromide or iodide. The quantum dot material may include core-shell nanostructures having an Ag—In—Ga—S (AIGS) core and an Ag—Ga—S (AGS) shell.

All of the semiconductor quantum dots may also have appropriate shells or coatings for passivation and/or environmental protection. The QD materials may be a core/shell QD, including a core, at least one shell coated on the core, and an outer coating including one or more ligands, preferably organic polymeric ligands. Exemplary materials for preparing core-shell QDs include, but are not limited to, Si, Ge, Sn, Se, Te, B, C (including diamond), P, Co, Au, BN, BP, BAs, AlN, AlP, AlAs, AlSb, GaN, GaP, GaAs, GaSb, InN, InP, InAs, InSb, AlN, AlP, AlAs, AlSb, GaN, GaP, GaAs, GaSb, ZnO, ZnS, ZnSe, ZnTe, CdS, CdSe, CdSeZn, CdTe, HgS, HgSe, HgTe, BES, BeSe, BeTe, MgS, MgSe, MnS, MnSe, GeS, GeSe, GeTe, SnS, SnSe, SnTe, PbO, PbS, PbSe, PbTe, CuF, CuCl, CuBr, CuI, Si₃N₄, Ge₃N₄, Al₂O₃, [Al, Ga, In]₂[S, Se, Te]₃, and appropriate combinations of two or more such materials. Exemplary core-shell luminescent nanocrystals include, but are not limited to, CdSe/ZnS, CdSe/CdS, CdSe/CdS/ZnS, CdSeZn/CdS/ZnS, CdSeZn/ZnS, InP/ZnS, PbSe/PbS, PbSe/PbS, CdTe/CdS and CdTe/ZnS.

In some embodiments, the quantum dot material includes perovskite quantum dots. In one embodiment, the perovskite quantum dot may be CsPbX3, wherein X is Cl, Br, I or a combination thereof. The mean size of the QD materials may range from about 2 nm to about 20 nm. The surface of QD particles may be further modified with ligands such as amine ligands, phosphine ligands, phosphatide and polyvinylpyridine. In one aspect, the red phosphor may be a quantum dot material.

In some embodiments, quantum dots in a color filter (QDCF) are utilized. QDCF may improve the color quality, viewing angle and energy efficiency of displays. By using a blue light source such as OLED, LED, mini-LED, or micro-LED, or a UV light source, and replacing traditional color filters with a QDCF material, at least a portion of the blue light gets converted to a higher wavelength range such as red and/or green light.

Other additional luminescent materials suitable for use in the color conversion layer may include electroluminescent polymers such as polyfluorenes, preferably poly(9,9-dioctyl fluorene) and copolymers thereof, such as poly(9,9′-dioctylfluorene-co-bis-N,N′-(4-butylphenyl)diphenylamine) (F8-TFB); poly(vinylcarbazole) and polyphenylenevinylene and their derivatives. In addition, the light emitting layer may include a blue, yellow, orange, green or red phosphorescent dye or metal complex, a quantum dot material, or a combination thereof. Materials suitable for use as the phosphorescent dye include, but are not limited to, tris(1-phenylisoquinoline) iridium (III) (red dye), tris(2-phenylpyridine) iridium (green dye) and iridium (III) bis(2-(4,6-difluorephenyl)pyridinato-N,C2) (blue dye). Commercially available fluorescent and phosphorescent metal complexes from ADS (American Dyes Source, Inc.) may also be used. ADS green dyes include ADS060GE, ADS061GE, ADS063GE, and ADS066GE, ADS078GE, and ADS090GE. ADS blue dyes include ADS064BE, ADS065BE, and ADS070BE. ADS red dyes include ADS067RE, ADS068RE, ADS069RE, ADS075RE, ADS076RE, ADS067RE, and ADS077RE.

The ratio of each of the individual phosphors and other luminescent materials in the color conversion layer may vary depending on the characteristics of the desired light output. The relative proportions of the individual phosphors and other luminescent materials in the color conversion layer or layers may be adjusted such that when their emissions are blended and employed in a device, for example a lighting apparatus, there is produced visible light of predetermined x and y values on the CIE chromaticity diagram.

In some embodiments, the color conversion layer further includes a scattering aid. Examples of scattering particles include, but are not limited to titanium dioxide, aluminum oxide (Al₂O₃), zirconium oxide, indium tin oxide, cerium oxide, tantalum oxide, zinc oxide, magnesium fluoride (MgF₂), calcium fluoride (CaF₂), strontium fluoride (SrF₂), barium fluoride (BaF₂), silver fluoride (AgF), aluminum fluoride (AlF₃) or combinations thereof. In some embodiments, the scattering aid is ZrO₂ or TiO₂ nanoparticles.

In one embodiment, the device includes a substrate. The substrate provides support to the color conversion layer and may be any suitable substrate known in the art that facilitates the device. The substrate may be rigid or flexible. In some embodiments, the substrate may be metal, glass, plastic or combinations. In one embodiment, the substrate may be a polymeric material, such as polyethylene terephthalate (PET) or polyvinylidene fluoride (PVDF).

In some embodiments, the substrate has reflective properties. In some embodiments, the substrate includes a reflective surface having at least 20% reflectivity of UV or visible light. In another embodiment, the substrate reflects at least 30% UV or visible light. In another embodiment, the substrate has a reflectivity of at least 40%. In some embodiments, the substrate reflects at least 50% of UV or visible light. In another embodiment, the substrate has a reflective surface with at least 55% reflectivity, at least 60%, at least 65%, at least 70%, at least 75%, at least 80%, at least 85%, at least 90% or at least 95%. In another embodiment, the substrate has a reflectivity from about 20% to 100%. In another embodiment, the substrate has a reflectivity from about 30% to 100%. In another embodiment, the substrate has a reflectivity from about 40% to 100%. In another embodiment, the substrate has a reflective surface of at least 50% to 100% reflectivity. In another embodiment, the surface has a reflectivity from at least about 60% to 100%. In another embodiment, the surface has a reflectivity from at 70% to 100%. In another embodiment, the substrate has a reflective surface having a reflectivity from about 80% to 100%. In another embodiment, the reflectivity of the surface is from about 90% to 100%.

In one embodiment, the substrate is a specular material. In another embodiment, the substrate is a metal including aluminum, aluminum alloys, chromium, gold, nickel, silver or silver alloys.

In another embodiment the substrate is coated with a diffuser layer. The diffuser layer may include one or more of titanium dioxide (TiO₂,), aluminum oxide (Al₂O₃), zirconium oxide (ZrO₂,), indium tin oxide, cerium oxide, tantalum oxide, zinc oxide, magnesium fluoride (MgF₂), calcium fluoride (CaF₂), strontium fluoride (SrF₂), barium fluoride (BaF₂), silver fluoride (AgF), aluminum fluoride (AlF₃) or combinations thereof. In other embodiments, additional additives improve film such quality, as Pentaerithritoltetrakis(3-mercaptopropionate) from Bruno Bock (BB PTh). The foregoing list is meant to be merely exemplary and not exhaustive. In one embodiment, the color conversion layer is located on the substrate. The color conversion layer has a first side and a second side and the color conversion layer is located on a first side of the substrate. The color conversion layer may be disposed on the substrate or other surface by any conventional manner. In one embodiment, the color conversion layer is applied to the substrate by coating the substrate with a luminescent composition, such as a phosphor composition, or by dipping the substrate in a phosphor composition and drying or curing the phosphor composition as described herein. In another embodiment, the phosphor composition may be an ink composition and the ink composition may be applied to the substrate by depositing or printing the ink composition. In some embodiments, a reflective layer may be disposed on the surface of the substrate and the phosphor composition may be applied to the reflective layer.

The phosphor composition may include a phosphor, a binder, a curing system and optionally, a solvent. The phosphor composition may include an additive. The phosphor is as previously described. In one embodiment, the phosphor may be a narrow-based emission phosphor, such as a Mn⁴⁺ doped phosphor or a uranium-based phosphor, a rare earth garnet phosphor, or a beta-SiAlON.

In some embodiments, the phosphor material may be present in the phosphor composition in an amount of about 0.1 wt % to about 20 wt %, based on the total weight of the phosphor composition. In some embodiments, the phosphor material is present in an amount of about 0.1 wt % to about 10 wt % based on the total weight of the phosphor composition. In another embodiment, the phosphor material may be present in the phosphor composition from about 5 wt % to about 70 wt %. In another embodiment, the phosphor material is present from about 30 wt % to about 60 wt %. In another embodiment, the phosphor material is present from about 10 wt % to about 50 wt %. The wt % for the phosphor material is based on the total weight of the phosphor composition.

In some embodiments, the phosphor composition includes a binder. A wide variety of binders and resin systems, with different chemistries and viscosities may be used. The binder may be one or more of an epoxy, polyacrylate, silicone, methacrylate, vinyl ester and siloxane. In another embodiment, the binder material is transparent and includes curable materials, such as photocurable or UV-curable materials or thermally curable or thermoset binder materials or a combination thereof.

In some embodiments, a phosphor layer is formed by depositing or printing the phosphor composition on a surface using any of the techniques described herein. The surface may comprise a substrate (e.g., metal, glass, plastic or combinations thereof), a polymeric material, such as polyethylene terephthalate (PET) or polyvinylidene fluoride (PVDF), and/or any other surface described herein. The phosphor composition may be in form of an ink composition. The ink composition may be cured after it has been applied in a deposition technique described herein. The ink solution may also be coated onto a substrate or formed into a film. In one embodiment, the ink composition is subject to a suitable temperature for heat curing or to a suitable radiation wavelength for UV curing, such as less than 400 nm.

A thermally curable or thermoset binder material will polymerize or crosslink and form a cured resin binder matrix. Exemplary thermoset and UV binder materials include epoxy, acrylate, methacrylate, vinyl ester and siloxane families. Examples of suitable commercial resin systems include, but are not limited to, a Pixelligent UVG Curable ink base, Optical Adhesive (Norland 68T), Pixelligent PixJet SFZ-1 with 40 wt % ZrO₂ in acrylic formulation.

In one embodiment, a 2-step cure utilizing UV and thermal cure is applied to the ink composition. This system simultaneously contains both photosensitive groups and thermosensitive groups. The first curing process utilizes a UV cure to soft cure the material in place. The wavelength for polymerization initiation is less than 400 nm (to classify as UV cure). The second curing step is a thermal cure, which uses heat to initiate the remainder of the polymerization reaction. The second curing step acts as a binding or through-cure mechanism. In a film, the second step may reduce the volume of the deposited film through shrinkage. In another embodiment, the first curing process utilizes a thermal cure to soft cure the material in place and the second curing step is a UV cure to through-cure the shape or film.

One advantage of the 2-step cure approach for curing a film is that it can tune how much and at what point in the process the deposited film shrinks. Depending on the content of each polymerization initiator, concentration of PFS can be tailored through altering the film densification mechanism. A UV only curing system relies on UV radiation touching every surface and one cannot assume the curing of shadowed or deep areas. Thermal only cure is not typically fast and therefore “slumping” or segregation/skinning can occur in deposited inks. In one embodiment, a UV cure is used to “soft cure” followed by a thermal cure to “through-cure” the shape or film. The 2-step curing approach can also be used to form one feature over another cured feature by UV cure, followed by thermal cure to further “bond” the two layers together. In another embodiment, a thermal cure to “soft cure” followed by a UV cure to “through-cure” the shape or film is used.

In some embodiments, the phosphor composition may include a solvent. The amount of solvent, solvent polarity, and solvent vapor pressure can aid in making a composition that meets desired viscosity, wettability, and optical density criteria. The solvent may be present in an amount effective for dissolving the phosphor material and any binder material and for adjusting the composition to a desired viscosity. In one embodiment, the solvent may be present from about 5 wt % to about 95 wt %. In another embodiment, the solvent may be present from about 10 wt % to about 75 wt %. In another embodiment, the solvent is present from about 20 wt % to about 50 wt %. The wt % of the solvent is based on the weight of the composition. Suitable solvents have a boiling point and polarity that match to the desired application and do not interact poorly with the binder material or phosphors used.

The solvents may be polar or non-polar. Examples of solvents include, but are not limited to acetone, glycol ethers, such as diethylene glycol methyl ether, propylene methyl acrylates, such as propylene glycol dimethyl acrylate, cyclic aromatic solvents, such as toluene, xylenes and anisol, aliphatic solvents, such as hexane and tetradecane, alcohols, such as ethanol, isopropanol, and octanol, glycols, such as ethylene glycol and propylene glycol, terpineol, acetates, such as butyl acetate, propylene glycol methyl ether acetate (PGMEA), N-methyl pyrrolidone (NMP), dimethyl sulfoxide (DMSO), dimethyl formamide (DMF), diethylene glycol methyl ether (DGME) and 2-(2-Butoxyethoxy)ethyl acetate (BEA).

Co-solvents and mixture of solvents can also be used. Mixture of solvents can be composed of any two or more of the solvents listed above and can also be comprised of small additions of common organic solvents into one of the solvents above.

The phosphor ink composition may have a viscosity from about 10 cP to about 30,000 cP. In another embodiment, the viscosity is from about 1000 cP to about 30,000 cP.

In some embodiments, the phosphor composition has a low viscosity. The low viscosity phosphor composition includes a viscosity in the range of from about 10 cP to about 1000 cP or less than 1000 cP. It can be easier for particles to settle out of a low viscosity film precursor, so it is desired to include very small particle sizes of the phosphor material.

In one embodiment, the phosphor composition has a medium viscosity. The medium viscosity phosphor composition includes a viscosity in a range from about 1,000 cP to about 10,000 cP. In another embodiment, the viscosity is in a range from greater than 1,000 cP to less than 10,000 cP.

In one embodiment, the phosphor composition has a high viscosity. The high viscosity phosphor composition includes a viscosity in a range from about 10,000 cP to about 30,000 cP. In another embodiment, the viscosity is in a range from greater than 10,000 cP to about 30,000 cP.

The viscosity ranges are for starting viscosity ranges in the phosphor compositions.

In one embodiment, the phosphor composition may be subject to a suitable temperature for heat curing or to a suitable radiation wavelength for UV curing, such as less than 400 nm. In another embodiment, the phosphor composition may be dried or partially cured.

In one embodiment, the phosphor composition is an ink composition. The ink composition includes a phosphor, at least one binder, a curing system and optionally, a solvent. The phosphor is as previously described. In one embodiment, the phosphor may be a narrow-based emission phosphor, such as a Mn⁴⁺ doped phosphor or a uranium-based phosphor, a rare earth garnet phosphor, or a beta-SiAlON. The phosphor has a D50 particle size from about 0.5 microns to about 15 microns and the ink composition has a viscosity from about 10 cP to about 30,000 cP. In another embodiment, the ink composition has a viscosity from about 1000 cP to about 30,000 cP. In another embodiment, the viscosity may be more than 2000 cP to about 30,000 cP.

The ink composition may be tailored to a specific printing application. For example, the ink composition may be tailored to any one of the following printing applications: inkjet printing, flexographic printing, or microdispensing printing, screen printing, direct write printing, aerosol jet printing, gravure printing, stencil printing, and the like. Additionally, or alternatively, the ink composition may be tailored for extrusion. For example, low viscosity ink compositions may be tailored for inkjet printing, flexographic printing, and/or microdispensing printing; medium viscosity inks may be tailored for screen printing, direct write printing, aerosol jet printing, gravure printing, flexographic printing, and/or microdispensing printing; and high viscosity inks may be tailored for high viscosity screen printing, direct write printing, and/or extruding. In one embodiment, the ink composition may be printed on a plastic or glass substrate. In another embodiment, the ink composition is printed on a PET or PVDF substrate.

The phosphor material may be present in the ink composition from about 0.1 wt % to about 20 wt %. In some embodiments, the phosphor material may be present from about 5 wt % to about 70 wt %. In another embodiment, the phosphor material is present from about 30 wt % to about 60 wt %. In another embodiment, the phosphor material is present from about 10 wt % to about 50 wt %. The wt % for the phosphor material is based on the total weight of the ink composition.

Additional additives may be added to the ink composition to further tailor the ink properties or film properties, such as adhesion or cohesion, light scattering, evaporation rate, stability, shelf life, etc.

In one embodiment, the ink composition includes a scattering aid, such as ZrO₂ nanoparticles. Examples of scattering particles include, but are not limited to titanium dioxide, aluminum oxide (Al₂O₃), zirconium oxide, indium tin oxide, cerium oxide, tantalum oxide, zinc oxide, magnesium fluoride (MgF₂), calcium fluoride (CaF₂), strontium fluoride (SrF₂), barium fluoride (BaF₂), silver fluoride (AgF), aluminum fluoride (AlF₃) or combinations thereof. In other embodiments, additional additives improve film quality, such as Pentaerithritoltetrakis(3-mercaptopropionate) from Bruno Bock (BB PTh).

Additives may be added to the ink composition in an amount of from about 5 wt % to about 20 wt %, based on the weight of the ink composition.

In one embodiment, the color conversion layer includes one or more films. The color conversion layer has a first side and a second side. In one embodiment, the first side and the second side of the color conversion layer are opposite to one another. In one embodiment, a second side of the color conversion layer is disposed or located on a first side of the substrate.

In one embodiment, the color conversion layer includes a film. The film includes phosphor material dispersed within a binder material in the form of a binder matrix. In one embodiment, the binder matrix includes a crosslinked polymer, such as one or more of polyepoxy, polyacrylate, polymethacrylate, polyvinyl ester and polysiloxane. In some embodiments, the color conversion layer includes a narrow-band emission phosphor film including PFS or NFS in a polymer matrix. In another embodiment, the color conversion layer may include a narrow-band emission phosphor film including a uranium-based phosphor in a polymer matrix.

In some embodiments, the film includes phosphors with micron or sub-micron particle sizes. In other embodiments, the film includes nano-sized particles.

In some embodiments, the phosphor may be present in the film in an amount of about 0.1 wt % to about 20 wt %, based on the total weight of the film. In some embodiments, the phosphor is present in an amount of about 0.1 wt % to about 10 wt % based on the total weight of the phosphor layer or film.

In one embodiment, the binder material may be present in an amount up to about 75 wt %. In another embodiment, the binder may be present in an amount up to about 70 wt %. In another embodiment, the binder may be present in an amount from about 5 wt % to about 75 wt %. In another embodiment, the binder is present in an amount of from about 10 wt % to about 70 wt %. In another embodiment, the binder is present from about 20 wt % to about 50 wt %. The weight % is based on total weight of the film.

Generally, the film may include any suitable further additive or other component known in the art that facilitates the device. Additives may be added to the film in an amount of from about 5 wt % to about 20 wt %, based on the weight of the film. In one embodiment, the film includes scattering agents, such as titanium dioxide, aluminum oxide (Al₂O₃), zirconium oxide, indium tin oxide, cerium oxide, tantalum oxide, zinc oxide, magnesium fluoride (MgF₂), calcium fluoride (CaF₂), strontium fluoride (SrF₂), barium fluoride (BaF₂), silver fluoride (AgF), aluminum fluoride (AlF₃) or combinations thereof. In some embodiments, the scattering aid is ZrO₂ or TiO₂ nanoparticles. Scattering agents provide an increased effective path length for the blue light and increase blue light absorption in the phosphor film or phosphor layer.

The films may have any desirable thickness. For films including Mn⁴⁺ doped phosphors having formula I, thicker films provide improved blue to red conversion. For thinner films, it is preferrable to include Mn⁴⁺ doped phosphors with small particle sizes and having a Mn content of at least 1.4 wt %.

A color conversion film may be deposited on the substrate or other surface, such as a reflective layer, by coating or printing a phosphor composition on the substrate or other surface and curing, partially curing or drying the phosphor composition. In one embodiment, a color conversion film may be prepared by depositing an ink composition on the substrate or reflective layer by coating, such as by using a doctor's blade, spin coating or slot die coating. In one embodiment, a film is prepared by coating the ink composition on a substrate with a doctor's blade. The solvent may then be removed and the film cured, such as by UV light or heat curing. In one embodiment, a film is prepared by partially curing an ink composition, such as by UV light or heat curing (e.g., UV light or heat is used to remove a portion of the solvent). The film is then deposited and fully cured, such as by UV light or heat curing (e.g., UV light or heat is used to remove the remaining solvent and crosslink the binder matrix). By partially curing, depositing the film and then fully curing, a film may better adhere to the substrate. In some embodiments, a reflective layer is applied to the substrate and the color conversion film may be deposited on the reflective layer as explained above.

In another embodiment, a color conversion film may be prepared by depositing an ink composition on the substrate or reflective layer or surface by printing, such as by ink jet printing, flexographic printing, microdispensing printing, screen printing, direct write printing, aerosol jet printing, gravure printing, stencil printing, lithography, and the like. The ink composition may be dried, cured or partially cured. In one embodiment, a 2-step cure utilizing UV and thermal cure is applied to the ink composition. This system simultaneously contains both photosensitive groups and thermosensitive groups. The first curing process utilizes a UV cure to soft cure the material in place. The wavelength for polymerization initiation is less than 400 nm (to classify as UV cure). The second curing step is a thermal cure, which uses heat to initiate the remainder of the polymerization reaction. The second curing step acts as a binding or through-cure mechanism. The 2-step curing approach can also be used to form one feature over another cured feature by UV cure, followed by thermal cure to further “bond” the two layers together.

The color conversion layer may have any desirable thickness. A thicker layer can improve color conversion. In one embodiment, the color conversion layer may be one or more films have a thickness from about 1 mil to about 10 mil. In another embodiment, the film thickness may be from about 2 mil to about 8 mil. In another embodiment, the film thickness may be from about 2 mil to about 6 mil. In another embodiment, the film thickness may be from about 3 mil to about 6 mil. In another embodiment, the film thickness may be from about 0.1 mm to about 10 mm. In another embodiment, the film thickness may be from about 0.1 mm to about 1 mm.

In some embodiments, a plastic layer or film may be placed on the excitation side of the color conversion film to change optical properties or improve reliability. For example, the plastic layer or film can act as a protective layer and protect the deposited ink from oxygen or moisture, can improve excitation source light coupling into the color conversion layer (for example an anti reflection layer), create a more diffuse excitation source entering the color conversion layer or a more uniform phosphor emission light exiting the color conversion layer. In one embodiment, the plastic layer of film, which may be a plastic layer or film with a low refractive index. The plastic layer or film may include polyethylene terephthalate (PET) or PVDF. In one embodiment, the substrate is glass, PET or PVDF, a color conversion layer is located on the substrate and a PVDF or other type of Plastic or film is located on the color conversion layer, such that the color conversion layer is sandwiched between the substrate and the PVDF diffusive layer. In another embodiment, a color conversion layer is sandwiched between a PVDF substrate and a PVDF plastic or film.

In one aspect, the device includes a color conversion layer including at least two films having different refractive indices. In one embodiment, the color conversion layer includes a film having a low refractive index and a film having a high refractive index. In some embodiments, the films has a refractive index of about 0.1 to about 3. In further embodiments, the films have a refractive index of about 1 to about 1.6 or from about 1 to 1.5. In one embodiment, one film has a refractive index of no more than 1.51 and another film has a refractive index greater than 1.51. In one embodiment, one film has a refractive index less than 1.53 and another film has a refractive index greater than 1.6.

In one embodiment, bilayer film structure may be prepared by a two-pass printing approach.

In one aspect, the device includes a reflective layer. The reflective layer is disposed between the substrate and the color conversion layer. In one embodiment, the reflective layer may be a specular material. In another embodiment, the reflective layer may be a metallic layer, such as aluminum, aluminum alloys, chromium, gold, nickel, silver or silver alloys. In another embodiment, the reflective layer is diffuse reflection and may include scattering agents, such as barium sulfate (BaSO₄), titanium dioxide (TiO₂) or zirconium dioxide (ZrO₂). In another embodiment, the reflective layer may be a paint that is applied to the substrate and the paint includes scattering agents.

In some embodiments, the reflective layer has at least 20% reflectivity of UV or visible electromagnetic emissions. In another embodiment, the reflective layer has at least 30% reflectivity, at least 40% reflectivity or at least 50% reflectivity of UV or visible electromagnetic emissions. In another embodiment, the reflective layer has a reflectivity of at least about 55%, at least 60%, at least 65%, at least 70%, at least 75%, at least 80%, at least 85%, at least 90% or at least 95%. In another embodiment, the reflective layer has a reflectivity from about 20% to 100%. In another embodiment, the reflective layer has a reflectivity from about 30% to 100% or from about 40% to 100%. In another embodiment, the reflective layer has a reflectivity from about 50% to 100%. In another embodiment, the reflective layer has a reflectivity from about 60% to 100%. In another embodiment, the reflective layer has a reflectivity from about 70% to 100%. In another embodiment, the reflective layer has a reflectivity from about 80% to 100%. In another embodiment, the reflective layer has a reflectivity from about 90% to 100%.

In one aspect, the device includes a back reflective layer. The back reflective layer is located on the second surface of the substrate at the back of the device. The back reflective layer may be any material suitable for reflecting light. In one embodiment, the back reflective layer may be a specular material. In another embodiment, the back reflective layer may be a metallic layer, such as aluminum, silver, silver alloys or aluminum alloys, chromium, gold or nickel. In one embodiment, the back reflective layer may be mirrored aluminum.

Generally, the light source includes any suitable light source known in the art that facilitates the device. In some embodiments, the light source includes a single light source. In some embodiments, the light source includes a plurality of light sources. In some embodiments, the light source includes an LED light source. In some embodiments, the LED light source includes a UV emitting LED or a blue emitting LED. In some embodiments, the LED light source includes a mini-LED or a micro-LED. Mini-LEDs are LEDs that are sized from about 100 μm to 0.4 mm. In one embodiment, a mini-LED is sized less than or equal to 250 microns. For example, a mini-LED may comprise an LED that has a length of 250 microns and a width of 250 microns. A micro-LED is an LED that is sized less than or equal to 50 microns. For example, a micro-LED may comprise an LED that has a length of 50 microns and a width of 50 microns. The display may include an array of LEDs.

The general discussion of the example LED light source discussed herein is directed toward an inorganic LED based light source. Many white LEDs are based on blue or UV emitting GaInN chips. In addition to inorganic LED light sources, the term LED light source is meant to encompass all LED light sources, such as semiconductor laser diodes (LD), organic light emitting diodes (OLED) or a hybrid of LED and LD. The LED light source may be a mini-LED or micro-LED, which can be used in self-emissive displays. Further, it should be understood that the LED light source may be replaced, supplemented or augmented by another radiation source unless otherwise noted and that any reference to semiconductor, semiconductor LED, or LED chip is merely representative of any appropriate radiation source, including, but not limited to, LDs and OLEDs.

In one embodiment, the device includes a color conversion layer disposed or located on a substrate having a reflectivity of greater than 20%. FIG. 1 shows a device 100 according to one embodiment of the present disclosure. Device 100 includes a color conversion layer 104 having a first side 103 and a second side 105 and a substrate 102 having a first side 101. The second side 105 of the color conversion layer 104 is located on the first side 101 of the substrate 102. Device 100 also includes a light source 106 located remotely from color conversion layer 104.

In one embodiment, the substrate 102 has a reflectivity greater than 20%. In one embodiment, the substrate 102 is a specular material. Specular materials have a reflectivity of at least 80% of visible or UV light and may include metals, such as aluminum, aluminum alloys, chromium, gold, nickel, silver or silver alloys. In one embodiment, the substrate 102 is a metal selected from aluminum, aluminum alloys, chromium, gold, nickel, silver or silver alloys.

The remote light source 106 is optically coupled and/or radiationally connected to color conversion layer 104 and irradiates color conversion layer 104 through at least the first side 103 of color conversion layer 104. The blue or UV light from the light source travels in an attenuated manner through the color conversion layer 104 and can be absorbed by luminescent materials within color conversion layer 104. Light that is not absorbed may pass through color conversion layer 104 and contact substrate 102. A substrate 102 having a reflectivity of at least 20% will reflect a portion of the blue or UV light back through the color conversion layer 104 where the blue or UV light again travels through color conversion layer 104 where it can illuminate luminescent materials, such as phosphor material, that are present before exiting color conversion layer 104. Radiance emitted from excited luminescent materials, such as phosphor material, can be emitted in any direction and some light may exit color conversion layer 104 at the second side 105. Light exiting the second side 105 of color conversion layer 104 will contact substrate 102, which will reflect at least 20% of the light back through color conversion layer 104 where it can emerge from the first side 103 of color conversion layer 104. Increasing the pathways for the UV/blue light through the color conversion layer improves blue absorbance and phosphor emission intensity.

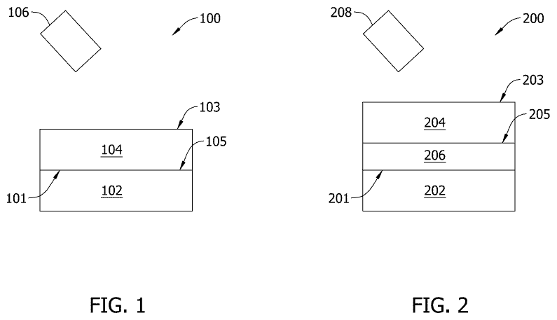

FIG. 2 shows a device 200 according to another embodiment of the present disclosure. Device 200 includes a color conversion layer 204 having a first side 203 and a second side 205 and a substrate 202 having a first side 201. The second side 205 of the color conversion layer 204 is located on the first side 201 of the substrate 202. Substrate 202 includes a reflective layer 206 located between the color conversion layer 204 and the substrate 202.

Substrate 202 may be any suitable substrate. In some embodiments, the substrate may be metal, glass, plastic or combinations. In some embodiments, the substrate includes a metal and may be aluminum, aluminum alloys, chromium, gold, nickel, silver or silver alloys. In some embodiments, the substrate is glass or plastic, such as PVDF or PET.

Reflective layer 206 may be a specular material or a diffuse reflective material with scattering agents. In some embodiments, reflective layer 206 may be a metallic layer, such as aluminum, aluminum alloys, chromium, gold, nickel, silver or silver alloys. In another embodiment, the reflective layer 206 may include a paint that is applied to the substrate 202 where the paint includes scattering agents, such as barium sulfate (BaSO₄), titanium dioxide (TiO₂) or zirconium dioxide (ZrO₂).

Device 200 also includes a light source 208 located remotely from color conversion layer 204. The remote light source 208 is optically coupled and/or radiationally connected to at least the first side 203 of color conversion layer 204 and irradiates color conversion layer 204 through the first side 203 of color conversion layer 204. The blue or UV light from the light source travels in an attenuated manner through the color conversion layer 204 and can be absorbed by luminescent materials that may be present within color conversion layer 204. Light that is not absorbed may pass through color conversion layer 204 and contact reflective layer 206. The reflective layer 206 will reflect a portion of the blue or UV light back through color conversion layer 204 where the blue or UV light again travels through color conversion layer 204 where it can illuminate phosphor material or other luminescent materials that are present before exiting color conversion layer 204.

Radiance emitted from excited luminescent materials, such as phosphor material, can be emitted in any direction and some of the light may exit color conversion layer 204 at the second side 205. Light exiting the second side 205 of the color conversion layer 204 will contact reflective layer 206, which will reflect at least a portion of the light back through the color conversion layer 204 where it can emerge from the first side 203 of the color conversion layer.

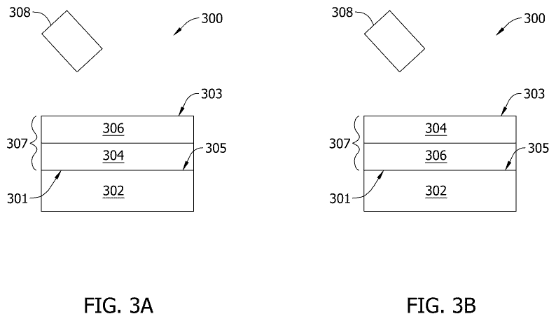

In one aspect, the device includes a color conversion layer including at least two films including luminescent material and having different refractive indices. FIG. 3A shows a device 300 according to another embodiment of the present disclosure. Device 300 includes a color conversion layer 307 having a first side 303 and a second side 305 and a substrate 302 having a first side 301. The color conversion layer 307 is disposed on the substrate 302, such that the second side 305 of the color conversion layer 307 is disposed on the first side 301 of substrate 302. Color conversion layer 307 includes two films 304, 306 having different refractive indices. Film 304 has a lower refractive index and is located on the first side 301 of substrate 302. Film 306 has a higher refractive index and is located on layer 304 opposite substrate 302. Substrate 302 may be any suitable substrate as described previously.

Color conversion layer 307 includes two films 304, 306 having different refractive indices. Film 304 has a lower refractive index than film 306. In one embodiment, films 304 and 306 may have a refractive index from about 0.1 to about 3. In another embodiment, the refractive index may be from about 1 to about 1.6 or from about 1 to about 1.5. In one embodiment, film 304 has a refractive index less than 1.53 and film 306 has a refractive index greater than 1.6.

Device 300 also includes a light source 308 located remotely from color conversion layer 307. The remote light source 308 is optically coupled and/or radiationally connected to color conversion layer 307 and irradiates color conversion layer 307 through at least the first side 303 of color conversion layer 307. The blue or UV light from the light source 308 travels in an attenuated manner through layer 306 and can be absorbed by luminescent materials present within film 306. Light that is not absorbed may exit film 306 and contact film 304, which has a lower refractive index. The difference in the refractive indices between films 304 and 306 will cause a reflection of a portion of the blue or UV light back through film 306 where the blue or UV light again travels through film 306 where it can be absorbed by luminescent material that are present in the film. Light that does enter into film 304 can also be absorbed by the luminescent materials within film 304.

Radiance emitted from excited luminescent materials can be emitted in any direction and some of the light may exit film 306 and contact film 304 having a lower refractive index. The difference in the refractive indices between films 304 and 306 will cause at least a portion of the light to reflect back through film 306 where it can emerge from the first side 303 of the color conversion layer 307.

FIG. 3B shows a device 300 according to another embodiment of the present disclosure. FIG. 3B is similar to FIG. 3A except that films 304 and 306 are switched, such that film 304 having a lower refractive index is disposed on film 306 having a higher refractive index and film 306 is located between film 304 and substrate 302. In one embodiment, the device includes a reflective layer and the color conversion layer includes two films having different refractive indices.

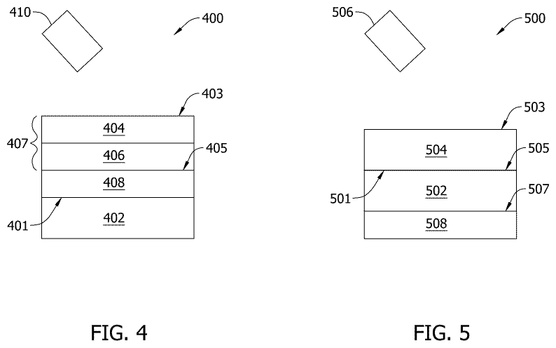

FIG. 4 shows a device 400 according to another embodiment of the present disclosure. Device 400 includes a color conversion layer 407 having a first side 403 and a second side 405 opposite the first side 403 and a substrate 402 having a first side 401. The second side 405 of the color conversion layer 407 is located on the first side 401 of the substrate 402. A reflective layer 408 is located between substrate 402 and color conversion layer 407. Color conversion layer 407 includes two films 404, 406 having different refractive indices. Film 404 has a lower refractive index and film 406 has a higher refractive index. In one embodiment, film 406 is located on reflective layer 408 and film 404 is located on film 406 opposite reflective layer 408.

Substrate 402 may be any suitable substrate. In some embodiments, the substrate may be metal, glass, plastic or combinations. In some embodiments, the substrate includes a metal and may be aluminum, aluminum alloys, chromium, gold, nickel, silver or silver alloys.

Reflective layer 408 may be a specular material or a diffuse reflective material with scattering agents. In some embodiments, reflective layer 408 may be a metallic layer, such as aluminum, aluminum alloys, chromium, gold, nickel, silver or silver alloys. In another embodiment, the reflective layer 408 may include a paint including scattering agents, such as barium sulfate (BaSO₄), titanium dioxide (TiO₂) or zirconium dioxide (ZrO₂). In one embodiment, the paint may be applied to substrate 402.

Color conversion layer 407 includes two films 404, 406 each including luminescent materials and having different refractive indices. Film 404 has a lower refractive index than film 406. In one embodiment, films 404 and 406 may have a refractive index from about 0.1 to about 3. In another embodiment, the refractive index may be from about 1 to about 1.6 or from about 1 to about 1.5. In one embodiment, film 404 has a refractive index less than 1.53 and film 406 has a refractive index greater than 1.6.

Device 400 also includes a light source 410 located remotely from color conversion layer 407. The remote light source 410 is optically coupled and/or radiationally connected to color conversion layer 407 and irradiates color conversion layer 407 through at least the first side 403 of color conversion layer 407. The blue or UV light from the light source 410 travels in an attenuated manner through film 404 having a lower refractive index and can be absorbed by luminescent materials present within the film 404. Light that is not absorbed may pass through film 404 and contact film 406, which has a higher refractive index. The difference in the refractive indices between films 404 and 406 will cause a reflection of a portion of the blue or UV light back through film 404 where the blue or UV light again travels through film 404 where it can be absorbed by luminescent materials that are present in the film. Light that does enter into film 406 can also be absorbed by the luminescent materials within film 406. Light that is not absorbed in film 406 may pass through film 406 and contact reflective layer 408. The reflective layer 408 will reflect a portion of the blue or UV light back through film 406 where the blue or UV light again travels through film 406 where it can illuminate luminescent materials.

Radiance emitted from excited luminescent materials can be emitted in any direction and some of the light may exit film 404 and contact film 406 having a higher refractive index. The difference in the refractive indices between films 404 and 406 will cause at least a portion of the light to reflect back through film 404 where it can emerge from the first side 403 of the color conversion layer 407. Radiance emitted in film 406 may exit film 406 at the second side 405 of color conversion layer 407. Light exiting the second side 405 of the color conversion layer 407 will contact reflective layer 408, which will reflect at least a portion of the light back through film 406.

In one embodiment, the device includes a back reflective layer. FIG. 5 shows a device 500 according to one embodiment of the present disclosure. Device 500 includes a color conversion layer 504 having a first side 503 and a second side 505, a substrate 502 having a first side 501 and a second side 507 and a back reflective layer 508. The second side 505 of the color conversion layer 504 is located on the first side 501 of the substrate 502 and the back reflective layer 508 is located on the second side 507 of the substrate 502. Device 500 also includes a light source 506 located remotely from color conversion layer 504.

The remote light source 506 is optically coupled and/or radiationally connected to color conversion layer 504 and irradiates color conversion layer 504 through at least the first side 503 of color conversion layer 504. The blue or UV light from the light source travels in an attenuated manner through the color conversion layer 504 and can be absorbed by luminescent materials within color conversion layer 504. Light that is not absorbed may pass through color conversion layer 504 and contact substrate 502. The substrate 502 may reflect a portion of the blue or UV light back through the color conversion layer 504 where the blue or UV light again travels through color conversion layer 504 where it can illuminate luminescent materials, such as phosphor material, that are present before exiting color conversion layer 504. Some light may continue through substrate 502 and contact back reflective layer 508. The back reflective layer 508 reflects the blue or UV light back through the substrate 502 toward the color conversion layer 504.

Radiance emitted from excited luminescent materials, such as phosphor material, can be emitted in any direction and some light may exit color conversion layer 504 at the second side 505. Light exiting the second side 505 of color conversion layer 504 will contact substrate 502, which will reflect a portion of the light back through color conversion layer 504 where it can emerge from the first side 503 of color conversion layer 504. Phosphor emission that passes through the substrate 502 may contact the back reflective layer 508, which will reflect the light back through the substrate 502 toward the color conversion layer 504. The device increases the pathways for the UV/blue light through the color conversion layer improves blue absorbance and phosphor emission intensity.

The back reflective layer 508 may be any material suitable for reflecting light. In one embodiment, the back reflective layer 508 may be a metallic layer, such as aluminum, silver, silver alloys or aluminum alloys, chromium, gold, nickel, silver or silver alloys. In one embodiment, the back reflective layer 508 is a specular material.

In one aspect, an article comprising the device as previously described is provided. Generally, the device may be included in any suitable article known in the art that facilitates the use of the device. Devices of the present disclosure include lighting and display apparatuses for general illumination and display applications

A display device or display provides information or images from a processor or other type of information management system by converting electrical signals into pixilated multicolor displays. Displays may be self-emissive, such as micro-LED or organic light emitting diode displays (OLED) with organic light emitting diode layers to produce light. A liquid crystal display (LCD) uses backlighting, such as from LED light sources and individual liquid crystal cells. Other devices include a direct emission display.

Devices of the present disclosure include lighting and display apparatuses for general illumination and display applications. Examples of display apparatuses include liquid crystal display (LCD) backlight units, televisions, computer monitors, automotive displays, laptops, computer notebooks, mobile phones, smartphones, tablet computers and other handheld devices. Where the display is a backlight unit, the phosphor composition may be incorporated in a film, sheet or strip that is radiationally coupled and/or optically coupled to the LED light source, as described in US Patent Application Publication No. 2017/0254943. The film, sheet or strip may be any film, sheet or strip described herein. Examples of other devices include chromatic lamps, plasma screens, xenon excitation lamps, UV excitation marking systems, automotive headlamps, automotive tail-lights, theatre projectors, laser pumped devices, and point sensors. In one embodiment, the device may be a fast response display that does not include an LCD. The fast response display may be a self-emissive display including phosphor converted (PC) micro-LEDs. In some embodiments, the device is a substantially transparent, fully transparent, and/or translucent display. For example, the device may comprise an automotive windshield. In some embodiments, the device comprises a heads-up display (e.g., any transparent display that presents data without requiring users to look away from their usual viewpoints). The heads-up display may comprise an automotive heads-up display, an aircraft heads-up display, a military vehicle heads-up display, an augmented reality (AR) heads-up display, and/or a virtual reality (VR) heads-up display. The list of these applications is meant to be merely exemplary and not exhaustive.

In some embodiments, an automotive tail-light having reflective geometry is provided. The automotive tail-light includes a plurality of LED light sources and a color conversion layer comprising luminescent material, the color conversion layer having a first side and a second side. The automotive tail-light further includes a substrate having a first side, the second side of the color conversion layer located on the first side of the substrate. The plurality of LED light sources are located remotely from the color conversion layer, wherein the LED light source is optically coupled and/or radiationally connected to at least the first side of the color conversion layer. The automotive tail-light includes at least one of: (a) the substrate has a reflectivity of at least 20%, (b) a reflective layer is located between the substrate and the color conversion layer, and/or (c) a back reflective layer located on the second side of the substrate.

In some embodiments, the article is selected from the group consisting of an illumination device, a lighting apparatus, a display apparatus, a backlight apparatus, a television, a mobile phone, a computer monitor, a laptop, a tablet computer, a computer notebook, chromatic lamps, solid state lighting products, transportation displays, vehicular displays, an automotive display, an aviation display, a self-emissive display, a transparent display, plasma screens, xenon excitation lamps, UV excitation marking systems, home and theater projections, digital photo frames, tablets, e-book reader, electronic dictionary, digital camera, computers, electronic keyboard, theatre projectors, laser pumped devices, point sensors, cellular or conventional phones, smartphones, gaming device, other handheld devices that have a display and other electronic devices with a screen, a windshield, an automotive light, an external light for an automotive or aviation display, an automotive tail-light, an automotive headlamp, and combinations thereof. In one embodiment, the device may be a fast response display that does not include an LCD. The fast response display may be a self-emissive display including phosphor converted (PC) micro-LEDs. In one embodiment, the display is a substantially transparent display, such as an automotive windshield. The list of these applications is meant to be merely exemplary and not exhaustive.

The display may be incorporated into various configurations, such as a film, sheet, strip, tiles or tiled parts.

Traditional backlight units use surface-mount device (SMD) LEDs. Traditional SMD LED chips are mounted on a holder and connected to a printed circuit board (PCB) by one or more alloy wires. The electrical current flows from the PCB board and through the alloy wires to power the LED chip. During use, too much heat or a surge in current can damage the alloy wires resulting in LED failure.

As the number of LEDs increase and the optical distance (OD) decreases, it may be preferable to use a chip-scale package (CSP). A CSP is a type of integrated circuit (IC) package that is surface mountable. CSP chips can be directly applied to the PCB effectively shortening the heat flow path to the substrate and reducing the thermal resistance of the light source. Under the same current, CSP chips have higher intensity and lower current consumed compared to SMD LED chips. And since the CSP LED chip has no chip holder or wires connected, two possible LED failure points are removed. Therefore, CSP LEDs features integrated component features that do not need soldered wire connections which reduce thermal resistance, reduce heat transfer path, reduce possible failure points, are smaller in size, have a high optical density, and do not require a substrate.

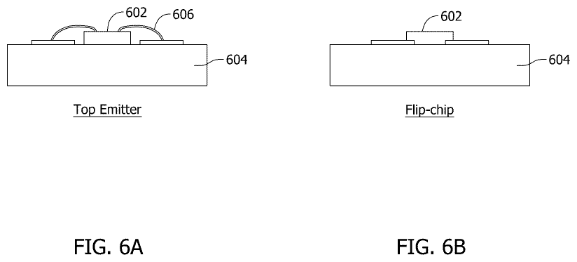

FIG. 6A illustrates a chip-on-board (COB) or chip-on-glass (COG) top emitting device. In the embodiment illustrated in FIG. 6A, an LED chip 602 is mounted on a backlight substrate 604. Backlight substrate 604 may comprise a PCB, a glass circuit board (GCB), or thin-film transistor (TFT) glass. In some embodiments, LED chip 602 is attached to backlight substrate 604 via an adhesive. In the embodiment illustrated in FIG. 6A, LED chip 602 is connected to backlight substrate 604 via one or more wires 606.

FIG. 6B is “flip chip” COB or COG. In flip COB or COG, the LED chip 602 is inverted, with a top layer of metallization facing the backlight substrate 604. Backlight substrate 604 may comprise a PCB, a glass circuit board (GCB), or thin-film transistor (TFT) glass. In some embodiments, small balls of solder are placed on the circuit board traces (not shown) where connections to the chip are required. In some embodiments, LED chip 602 and backlight substrate 604 are passed through a reflow soldering process to make the electrical connections.

CSPs offer advantages like smaller size (reduced footprint and thickness), lesser weight, relatively easier assembly process, lower overall production costs, and improvement in electrical performance. They are also tolerant of chip size changes since a reduced chip size can still be accommodated by the interposer design without changing the CSP's footprint. Further, a CSP LED may have a wider viewing angle of up to 180 degrees because the phosphor is applied on the sides too. This may be very important advantage for applications such as backlight modules, replacement of traditional form factor lamps and tubes.

The CSP product features integrated component features that do not need soldered wire connections which reduce thermal resistance, reduce heat transfer path, and reduce possible failure points. Therefore, in some applications, it may be preferable to use CSPs.

Ink formulations described herein may be implemented in CSPs, such as those illustrated in FIGS. 6A-6B. In some embodiments, such CSPs are used in applications such as LED headlights and various displays. In some embodiments, CSP chips may replicate the size and location of the tungsten filament in halogen bulbs to create beam patterns much like halogen bulbs.

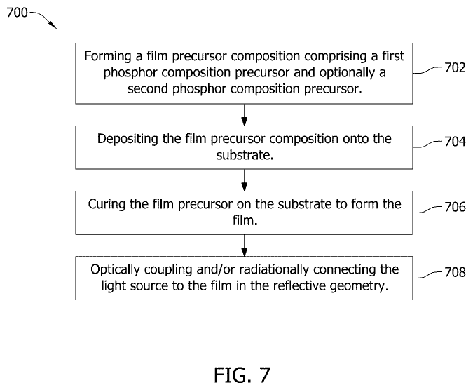

FIG. 7 is a flow diagram of an embodiment of an exemplary method 700 in accordance with the present disclosure. The method 700 includes forming 702 a phosphor composition including a narrow-band emission phosphor, a binder and optionally a solvent, depositing 704 the phosphor composition onto the substrate, curing 706 or partially curing the phosphor composition on the substrate to form a film, and optically coupling and/or radiationally connecting 708 the light source to the film in the reflective geometry.

In some embodiments, curing the film precursor includes exposing the film precursor to a curing condition selected from the group consisting of elevated temperature, irradiation, UV irradiation, and combinations thereof.

Without further elaboration, it is believed that one skilled in the art using the preceding description can utilize the present invention to its fullest extent. The following Examples are, therefore, to be construed as merely illustrative, and not limiting of the disclosure in any way whatsoever. The starting material for the following Examples may not have necessarily been prepared by a particular preparative run whose procedure is described in other Examples. It also is understood that any numerical range recited herein includes all values from the lower value to the upper value. For example, if a range is stated as 10-50, it is intended that values such as 12-30, 20-40, or 30-50, etc., are expressly enumerated in this specification. These are only examples of what is specifically intended, and all possible combinations of numerical values between and including the lowest value and the highest value enumerated are to be considered to be expressly stated in this application.

### EXAMPLES

### Equipment and Supplies.

The following equipment was used: weighing scale, hotplate, vortex mixer, ultrasonic sonicator bath, prob (horn) sonicator bottle roller; doctor blade.

### Materials.

The following components were used in the examples.

| Component | Abbreviation/Term |
|---|---|
| Diethylene glycol dimethyl | DGME |
| ether | |
| Acrylate Norland 68 | NOA68 |
| Titanium dioxide | TiO₂ |
| TPO-L (photo initiator) | 84434-11-7 |
| Pentaerythritoltetrakis (3- | BBPTh |
| mercaptopropionate) (BB- | |
| Pth) (Polythiol) | |
| 70% PixClear ® TiO₂ | SFT1 |
| dispersed in Acrylic | |
| Formulation | |
| TriGain Red | PFS-69F |
| Rust-Oleum ® flat enamel | flat enamel white |
| | paint containing |
| | TiO₂ |
| Rust-Oleum ® lacquer | white lacquer |
| | containing TiO₂ |
| Behr ® satin primer/paint | white satin |
| | primer/paint |
| | containing TiO₂ |

### Example 1. Formulations

TiO₂ reflective layer formulation 1.

2.2 g of DGME was added into a 20 ml amber vial containing 11.23 g of NOA68. The solvent-acrylate mixture was vortex mixed for 5 minutes until all bubbles vanished, which is a crucial step for subsequent thin film deposition. 9.84 g of TiO₂ in DGME was charged into the mixture, followed by meticulous vortex mixing for 1 minute and bath sonication for an additional 1 minute. Upon the addition of 0.2093 g of TPO-L, the mixture underwent vortex mixing for 1 minute before being left to roll overnight.

Film precursor 2 (ink formulation)—PFS film precursor with low refractive index.

1.91 g of DGME was added into a 20 ml amber vial containing 4.01 g of NOA68. The resulting mixture was meticulously mixed using vortex mixer until all bubbles vanished, indicating its readiness for additional ingredients.

6.38 g of potassium fluoro-silicate (PFS) phosphor powder (PFS-69F) was incrementally (<1 g each time) added into above acrylate-solvents mixture. This addition process involved repetitive and vigorous mixing on a vortex mixer for 1 minute, followed by bath sonication for 1 minute. Mixing steps were conducted after each addition of PFS-69F powder to enhance the suspension and reduce particle agglomeration. Once all the PFS-69F addition was finished, the film precursor was sonicated in a bath sonicator for 5 minutes. Scattering agent TiO₂ was prepared by pre-dispersing TiO₂ powder in DGME to form 51.9 wt % dispersion through a vigorous mixing on vortex mixer for 1 minute, followed by bath sonication for 20 min at room temperature.

0.303 g of TiO₂ in DGME was added dropwise into solvents-phosphors mixture following a vigorous mixing on vortex mixer for 1 min, bath sonication for 5 min, and probe sonication for 10 s in pulse mode (total run time ˜30 s) for 1 sec ON, 2 sec OFF. Amplitude was set to 27%. As a result, the film precursor included a total of 2.06 g of the solvent DGME. 0.096 g of photo initiator TPO-L was charged dropwise into mixture followed by vortex mixing for 1 min. The homogeneous suspension was rolled over night at lowest rolling speed.

All preparation procedures were conducted at room temperature. Prolonged exposure of the film precursor to ambient light may result in premature curing. Repeating the mixing steps for a homogeneous suspension did not show any adverse effects on the film precursor performance.

Film precursor 3 (ink formulation)—PFS film precursor with high refractive index.

0.77 g of BBPTh, 3.77 g of SFT1 and 1.50 g DGME were added into a 4-dram amber vial in sequence. The resulting mixture was meticulously vortex mixed for 1 minute followed by bath sonication for 1 minute.

7.00 g of PFS-69F was added in 5 aliquots into the above mixture. This addition process involved repetitive and vigorous mixing on a vortex mixer for 1 minute and bath sonication for 1 minute after each addition. Once all the PFS-69F addition was finished, DGME was incrementally (0.1-0.2 g each time) introduced into the mixture to tune the viscosity.

0.28 g of TiO₂ in DGME was added into the solvent-phosphors mixture, followed by adding additional DGME until desired viscosity occurred.

The mixture underwent a vigorous mixing on the vortex mixer for 1 minute, probe sonication for 30 seconds in pulse mode (total run time 3×30 seconds) for 1 second ON, 2 seconds OFF and bath sonication after each mixing series. Amplitude was set to 27%. The homogeneous suspension was rolled over night at lowest rolling speed.

### Example 2. Formulation Characterization

Viscosity: The viscosity of film precursor was measured with a rheometer (e.g., a DVNextRV from Brookfield/Ametek) at different shear rate levels using a spindle (e.g., a CPA-40Z spindle).

Surface tension: The surface tension of film precursor was measured with a tensiometer (e.g., a DuNouy Tensiometers).

### Example 3. Film Formation

Film precursors were deposited on 1″×1″ square glass substrates that had a thickness of 0.1 mm via doctor blade (DB) coating. The DB gap was adjusted to provide a maximum thickness of the deposited films. The coated substrates were placed on a hot plate at 100° C. for drying.

The dried, coated samples were then placed inside a ring fitted with a tube connected to nitrogen and the whole assembly was placed in a UV curing chamber. Flowing N₂ provided a blanket over the samples during the UV cure (3 min).

Using this coating method, several coating architectures were investigated, as defined in Table 1.

TABLE 1
Coating architectures.

| Example | Formulation | DB gap (mil) | Deposited on |
|---|---|---|---|
| FA | 1 | 0.5 | Bare glass |
| FB | 2 | 4 | Bare glass |
| FC | 3 | 4 | Bare glass |
| FD | 2 | 4 | FA |
| FE | 3 | 4 | FA |
| FF | 2 | 2 | Bare glass |
| FG | 3 | 2 | Bare glass |
| FH | 2 | 5 | FG |
| FI | 3 | 5 | FF |
| FJ | 2 | 4 (but with 0.45 mm | FE |
| | | thick tape on DB | |
| | | rails) | |
| FK | 2 | 4 | Bare glass spray- |
| | | | painted with flat |
| | | | enamel white paint |
| FL | 2 | 5 | Bare glass spray- |
| | | | painted with flat |
| | | | enamel white paint |
| FM | 2 | 6 | Bare glass spray- |
| | | | painted with flat |
| | | | enamel white paint |
| FN | 2 | 6 | Bare glass coated |
| | | | with a white satin |
| | | | primer/paint |
| FO | 2 | 4 | Bare glass spray- |
| | | | painted with white |
| | | | lacquer |
| FP | 3 | 4 | Bare glass spray- |
| | | | painted with flat |
| | | | enamel white paint |
| FQ | 3 | 4 | Bare glass spray- |
| | | | painted with white |
| | | | lacquer |

Films FP and PQ exhibited cracking and blistering of the film during the drying and UV cure steps.

### Example 4. Film Characterization

The coating architectures were characterized to determine their optical properties, as shown in Tables 2 and 3. Relative brightness was compared to the film with the highest measured plaque brightness in the absence of a reflective layer.

TABLE 2
Optical properties of films not deposited on a reflective layer.

| | Plaque | Relative | | |
|---|---|---|---|---|
| Example | brightness | brightness | EQE (BT) | Bleedthrough |
| FB | 80275 | 68.4% | 66.7% | 30.4% |
| FB | 84548 | 72.1% | 70.2% | 26.6% |
| FB | 88673 | 75.6% | 71.7% | 25.7% |
| FC | 84581 | 72.1% | 68.5% | 15.7% |
| FC | 80181 | 68.4% | 67.9% | 15.1% |
| FC | 78846 | 67.2% | 68.7% | 14.8% |
| FF | 29127 | 24.8% | 41.1% | 57.4% |
| FF | 30474 | 26.0% | 42.0% | 56.5% |
| FF | 25883 | 22.1% | 39.0% | 59.1% |
| FG | 51017 | 43.5% | 52.6% | 34.2% |
| FG | 54833 | 46.8% | 57.0% | 29.7% |
| FG | 58943 | 50.3% | 58.6% | 28.2% |
| FH | 117280 | 100.0% | 19.9% | 57.4% |
| FH | 114483 | 97.6% | 22.5% | 56.5% |
| FH | 102886 | 87.7% | 22.3% | 59.1% |
| FI | 76705 | 65.4% | 45.5% | 34.2% |
| FI | 79920 | 68.1% | 48.8% | 29.7% |
| FI | 72735 | 62.0% | 48.2% | 28.2% |

TABLE 3
Optical properties of films deposited on a reflective layer.

| | Plaque | Relative |
|---|---|---|
| Example | brightness | brightness |
| FD | 112513 | 95.9% |
| FD | 111013 | 94.7% |
| FD | 109072 | 93.0% |
| FE | 97151 | 82.8% |
| FE | 79655 | 67.9% |
| FE | 86344 | 73.6% |
| FJ | 106860 | 91.1% |
| FJ | 110832 | 94.5% |
| FJ | 103625 | 88.4% |
| FO | 108309 | 92.4% |
| FK | 137816 | 117.5% |
| FK | 191391 | 82.9% |
| FD | 139701 | 60.5% |
| FL | 131671 | 57.0% |
| FL | 221137 | 95.8% |
| FL | 205529 | 89.0% |
| FM | 215248 | 93.2% |
| FM | 226132 | 97.9% |
| FM | 191173 | 82.8% |
| FN | 230909 | 100.0% |
| FN | 179481 | 77.7% |

### Conclusion for Examples 1-4

It was discovered herein that devices including a reflective geometry between the light source and the film exhibit increased time and number of interactions between light from the light source and the film, which consequently increases color conversion, plaque brightness, and relative brightness and decreases bleed-through. It was particularly found that brightness was increased by at least 30%. As such, the devices of the present disclosure are especially useful for lighting and display applications.

### Example 5. Reflectivity

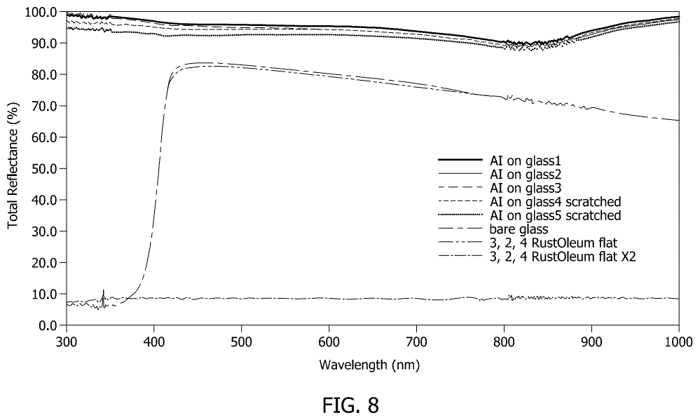

Substrate samples were coated with reflective surfaces to determine their reflectivity in the absence of the film composition. FIG. 8 depicts the reflectivity of these coated substrates by wavelength (nm) in relation to a bare glass substrate. It was observed that a mirrored aluminum coating on glass (Al on glass1, Al on glass2 and Al on glass3) or a mirrored aluminum coating on scratched glass (Al on glass4 scratched and Al on glass5 scratched) exhibited the highest total reflectance. Samples of bare glass substrates spray-painted with a white coating of Rust-Oleum® flat enamel (3,2,4 Rust-Oleum® flat and 3,2,4 Rust-Oleum® flat X2) also exhibited significant total reflectance.

### Example 6

The film “KSF low RI ink+TiO₂” is a film having a low refractive index (e.g., films with a refractive index of less than 1.53) that is prepared by printing a KSF phosphor ink containing 1.25% TiO₂ scattering particles. The film “High RI ink+KSF” is a film having a high refractive index (e.g., films with a refractive index of greater than 1.6) that is prepared by printing a KSF ink. Sample data is shown in Table 4.

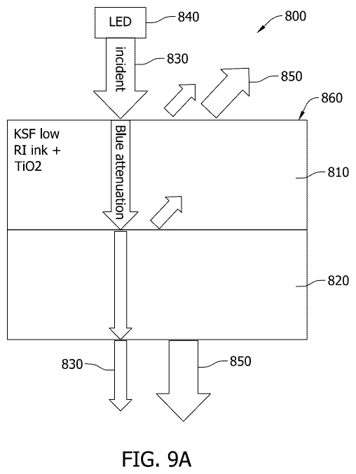

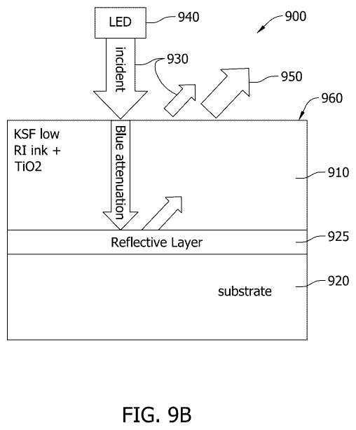

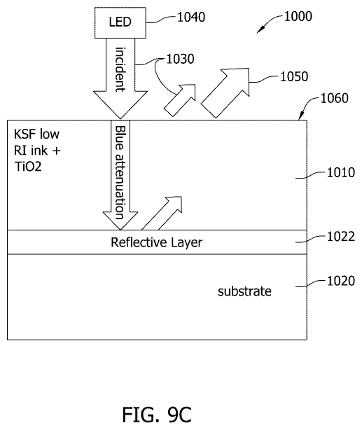

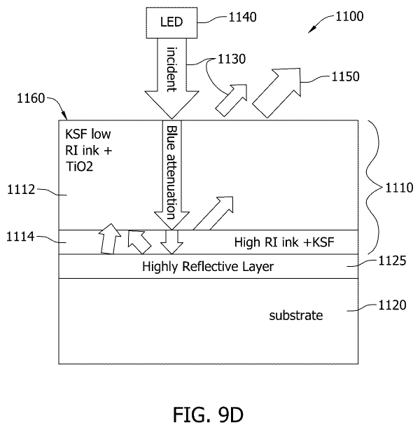

A control sample FR is shown in FIG. 9A. Control sample FR (800) contains KSF low RI ink film 810 having a thickness of 5 mils that was printed on a bare glass substrate 820. As shown in FIG. 9A, incident blue light 830 is emitted from a remote LED light source 840. The blue light 830 irradiates film layer 810 (KSF low RI ink film). The blue light 830 travels in an attenuated manner through film layer 810 and can be absorbed by and excite KSF phosphor materials within film layer 810 to emit red light 850. Radiance emitted from excited phosphor materials can be emitted in any direction. Red light 850 emitted in a desirable direction from a first surface 860 of the film layer 810 is measured and set at 100% red light emission. Some red light 850 passes through the glass substrate 820 and exits the substrate 820 in an undesirable direction and is not measured. Blue light 830 that is not absorbed by KSF phosphor materials in film layer 810 may exit film layer 810 or pass through the glass substrate 820. Unabsorbed blue light exiting control sample 800 is lost and not converted.

Sample FS is shown in FIG. 9B. Sample FS (900) contains KSF low RI ink film 910 having a thickness of 5 mils and a mirrored aluminum reflective layer 925. The KSF low RI ink film 910 was printed on a glass substrate 920 coated with a mirrored aluminum reflective layer 925. As shown in FIG. 9B, incident blue light 930 is emitted from a remote LED light source 940. The blue light 930 irradiates film layer 910 (KSF low RI ink film). The blue light 930 travels in an attenuated manner through film layer 910 and can be absorbed by and excite KSF phosphor material within film layer 910 to emit red light 950. Radiance emitted from excited phosphor materials can be emitted in any direction. Red light 950 emitted in a desirable direction from a first surface 960 of the film layer 910 is measured and shown in Table 4. The mirrored aluminum reflective layer 925 reflects red light 950 through film layer 910 to be emitted in a desirable direction from surface 960. The mirrored aluminum reflective layer 925 also reflects unabsorbed blue light 930 back through film layer 910 to where it can be absorbed by KSF phosphor material and emit red light 950.

Sample FT is shown in FIG. 9C. Sample FT (1000) contains KSF low RI ink film 1010 having a thickness of 6 mils and a diffuse reflective layer 1022 including white paint containing TiO₂. The KSF low RI ink film 1010 was printed on a glass substrate 1020 spray-coated with Rust-Oleum® flat enamel white paint containing TiO₂. As shown in FIG. 9C, incident blue light 1030 is emitted from a remote LED light source 1040. The blue light 1030 irradiates film layer 1010 (KSF low RI ink film). The blue light 1030 travels in an attenuated manner through film layer 1010 and can be absorbed by and excite KSF phosphor material within film layer 1010 to emit red light 1050. Radiance emitted from excited phosphor materials can be emitted in any direction. Red light 1050 emitted in a desirable direction from a first surface 1060 of the film layer 1010 is measured and shown in Table 4. The diffuse reflective layer 1022 reflects red light 1050 through film layer 1010 to be emitted in a desirable direction from surface 1060. The diffuse reflective layer 1022 also reflects unabsorbed blue light 1030 back through film layer 1010 to where it can be absorbed by KSF phosphor material and emit red light 1050.

Sample FU is shown in FIG. 9D. Sample FU (1100) has a bilayer film structure 1110 including the KSF low RI ink+TiO₂ film 1112 having a thickness of 6 mil and a High RI ink+KSF film 1114 having a thickness of 2 mil. The glass substrate 1120 was coated with a mirrored aluminum reflective layer 1125, and the High RI ink+KSF and the KSF low RI ink were printed on the coated glass substrate by a two-pass printing approach. As shown in FIG. 9D, incident blue light 1130 is emitted from a remote LED light source 1140. The blue light 1130 irradiates the bilayer film structure 1110. The blue light 1130 travels in an attenuated manner through the bilayer film structure 1110 and can be absorbed by and excite KSF phosphor material within film layer 1112 and film layer 1114 to emit red light 1150. Radiance emitted from excited phosphor material can be emitted in any direction. Red light 1150 emitted in a desirable direction from a first surface 1160 of the bilayer film structure 1110 is measured and shown in Table 4.

The bilayer film structure 1110 has two films 1112, 1114 with different refractive indices. Film 1112 has a low refractive index and film 1114 has a high refractive index. When unabsorbed blue light 1130 passes through film 1112 and contacts film 1114 having a different refractive index, the difference in the refractive indices causes a reflection of a portion of the blue light 1130 back through film 1112 where the blue light 1130 again travels through film 1112 where it can be absorbed by KSF phosphor material and emit red light 1150.

In some embodiments, bilayer film structure 1110 is formed by depositing two inks of two different indices on a substrate layer by layer and then drying or curing the ink to make films of two different indices. More particularly, a first ink composition having a first refractive index may be deposited on substrate 1120 and/or reflective layer 1125. The first ink composition is cured to form a first film. The first ink composition is cured using any curing technique described herein (e.g., UV curing and/or thermal curing). Next, a second ink composition having a second refractive index may be deposited on the first film. The first and second refractive indices are different. The second ink composition may be deposited after the first ink composition has cured and formed into a film. The second ink composition is then cured using any curing technique described herein (e.g., UV curing and/or thermal curing) to form a second film. Additionally, or alternatively, the first film and the second film are remotely and/or separately formed, and one of the first film or the second film are subsequently attached to the substrate 1120 and/or reflective layer 1125.

The mirrored aluminum reflective layer 1125 reflects red light 1150 through the bilayer film structure 1110 to be emitted in a desirable direction from surface 1160. The mirrored aluminum reflective layer 1125 also reflects unabsorbed blue light 1130 back through film layer 1114 to where it can be absorbed by KSF phosphor material and emit red light 1150.

Data for samples FR, FS, FT and FU is shown in Table 4.

TABLE 4

| | | % rel. red | | Total |
|---|---|---|---|---|
| Sample | Architecture | intensity | Std dev | samples |
| FR | 5 mil on glass, | 100% | 0.22 | 9 |
| | no reflector | | | |
| FS | 5 mil low RI, | 190% | 0.26 | 9 |
| | Al on glass | | | |
| FT | 6 mil low RI | 184% | 0.49 | 9 |
| | Rust-Oleum ® | | | |
| | flat | | | |
| FU (Film C) | 6 mil low RI | 180% | 0.51 | 10 |
| | film, 2 mil high | | | |
| | RI film, Al on | | | |
| | Glass | | | |

### Conclusion

It was discovered herein that devices including a reflective geometry between the light source and the KSF film exhibit increased time and number of interactions between the blue light from the light source and the KSF phosphor material, which consequently increases color conversion and red light intensity. Applying a reflective layer, such as a metal reflective layer (Sample FS) or a diffuse reflective layer (Sample FT), resulted in almost doubling the red light intensity (190% increase and 184% increase, respectively). Sample FU including an aluminum reflective layer and a bilayer film structure with different refractive indices showed a 1.8 increase over control sample FR. It is believed that optimizing the film thicknesses for the bilayer film structure and improving the transparency in the high refractive index film will further improve the red light intensity value for the device architecture.

### Example 7. Formulations

### TiO₂ Solution

A mixture of 50 wt % TiO₂ and 50 wt % DGME solution was prepared through vigorous vortex mixing for 1 minute followed by bath sonication for 20 minutes at room temperature.

Ink Solution 1—Na₂UO₂P₂O₇:Eu³⁺

1.7317 g of DGME was added into 20 ml amber vial containing 3.1403 g of NOA68. The solvent-acrylate mixture was vortex mixed for 5 min until all bubbles vanished, a crucial step for subsequent thin film deposition. Then 0.12 g of TiO₂ in DGME (TiO₂ solution) was charged into the mixture, followed by meticulous vortex mixing for 1 minute and bath sonication for an additional 1 minute. Upon the addition of 0.0587 g of TPO-L, the mixture underwent vortex mixing for 1 minute before being left to roll overnight. The phosphor was added in three additions for a total of 4.9923 g of Na₂UO₂P₂O₇:Eu³⁺. This addition process involved repetitive and vigorous mixing on a vortex mixer for 1 min, followed by bath sonication for 1 min. Mixing steps were conducted after each addition of Na₂UO₂P₂O₇:Eu³⁺ powder to enhance the suspension and reduce particle agglomeration. Once all the Na₂UO₂P₂O₇:Eu³⁺ addition was finished, the ink was sonicated in a bath sonicator for 5 min.

Ink Solution 2—Na₂UO₂P₂O₇:Sm³⁺

1.8459 g of DGME was added into 20 ml amber vial containing 3.3673 g of NOA68. The solvent-acrylate mixture was vortex mixed for 5 min until all bubbles vanished, a crucial step for subsequent thin film deposition. Then 0.135 g of TiO₂ in DGME (TiO₂ solution) was charged into mixture, followed by meticulous vortex mixing for 1 minute and bath sonication for an additional 1 minute. Upon the addition of 0.1 g of TPO-L, the mixture underwent vortex mixing for 1 minute before being left to roll overnight. The phosphor was added in three additions for a total of 5.3572 g of Na₂UO₂P₂O₇:Sm³⁺. This addition process involved repetitive and vigorous mixing on a vortex mixer for 1 min, followed by bath sonication for 1 min. Mixing steps were conducted after each addition of Na₂UO₂P₂O₇:Sm³⁺ powder to enhance the suspension and reduce particle agglomeration. Once all the Na₂UO₂P₂O₇:Sm³⁺ addition was finished, the ink was sonicated in a bath sonicator for 5 min.

Ink Solution 3—BaZnUO₂(PO₄)₂

1.804 g of DGME was added into 20 ml amber vial containing 3.2918 g of NOA68. The solvent-acrylate mixture was vortex mixed for 5 min until all bubbles vanished, a crucial step for subsequent thin film deposition. Then 0.1104 g of TiO₂ in DGME (TiO₂ solution) was charged into the mixture, followed by meticulous vortex mixing for 1 minute and bath sonication for an additional 1 minute. Upon the addition of 0.1 g of TPO-L, the mixture underwent vortex mixing for 1 minute before being left to roll overnight. The phosphor was added in three additions for a total of 5.2338 g of BaZnUO₂(PO₄)₂. This addition process involved repetitive and vigorous mixing on a vortex mixer for 1 min, followed by bath sonication for 1 min. Mixing steps were conducted after each addition of BaZnUO₂(PO₄) 2 powder to enhance the suspension and reduce particle agglomeration. Once all the BaZnUO₂(PO₄)₂ addition was finished, the ink was sonicated in a bath sonicator for 5 min.

The three inks (Ink Solution 1, Ink Solution 2 and Ink Solution 3) were used to Dr. blade coat films of 3 mil and 6 mil thickness on glass substrates (Samples 1 and 2), glass substrates with specular reflectors (Aluminum mirrored coating) (Samples 3 and 4) and glass substrate with diffuse reflectors (TiO₂ coating) (Samples 5 and 6). Brightness data is shown in Table 5.

TABLE 5

| | | | Brightness | Brightness | Brightness |
|---|---|---|---|---|---|
| | | Film | average | average | average |
| Sample | Substrate | Thickness | (ink 1) | (ink 2) | (ink 3) |
| 1 | Glass | 3 mil | 701 | 414 | 818 |
| 2 | Glass | 6 mil | 911 | 485 | 940 |
| 3 | Al coating | 3 mil | 1556 | 570 | 1438 |
| 4 | Al coating | 6 mil | 1783 | 658 | 1655 |
| 5 | TiO₂ coating | 3 mil | 1503 | 544 | 1051 |
| 6 | TiO₂ coating | 6 mil | 1714 | 617 | 1354 |

### Results

The results show that in a reflective geometry that the thicker films (6 mil) (Samples 2, 4, and 6) are brighter than the thinner films (3 mill) (Samples 1, 3 and 5) and that the mirrored coatings (Samples 3 and 4) are brighter than the TiO₂ coating (Samples 5 and 6) and the bare glass substrate (Samples 1 and 2) at a given thickness.

### Example 8. Automotive Lighting Specifications

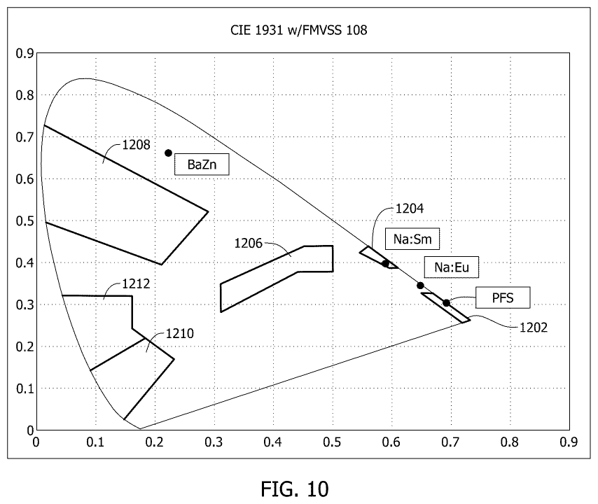

FIG. 10 shows a CIE 1931 graph (ccx vs ccy) plotting the Federal Motor Vehicle Safety Standard 108 (FMVSS 108) color point requirements for U.S. automotive lighting (from S14.4.1.4.2). The color point requirements for colors Red 1202, Yellow (Amber) 1204, White (achromatic) 1206, Green 1208, Restricted Blue 1210 and Signal Blue 1212 are plotted on the graph. PFS (PFS-69F from Example 1

Color points for phosphors PFS (PFS-69F from Example 1), BaZnUO₂(PO₄)₂ (from Ink Solution 3 in Example 7), Na₂UO₂P₂O₇:Eu³⁺ (from Ink Solution 1 in Example 7) and Na₂UO₂P₂O₇:Sm³⁺ (from Ink Solution 2 in Example 7) are plotted within the graph in FIG. 10. PFS phosphor falls within the color point requirement for Red and Na₂UO₂P₂O₇:Sm³⁺ falls within the color point requirement for Yellow (Amber). Color points for phosphors BaZnUO₂(PO₄)₂ and Na₂UO₂P₂O₇:Eu³⁺ do not fall within the color point requirements alone, but can be blended with other phosphors to obtain a desired color point.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A device comprising:
a color conversion layer comprising luminescent material, the color conversion layer having a first side and a second side;
a substrate having at least 20% reflectivity, the substrate having a first side;
the second side of the color conversion layer located on the first side of the substrate;
an LED light source located remotely from the color conversion layer, wherein the LED light source is optically coupled and/or radiationally connected to at least the first side of the color conversion layer.

2. The device according to claim 1, wherein the color conversion layer comprises one film or at least two films having different refractive indices.

3. The device according to claim 2, wherein the luminescent material comprises phosphor material selected from yttrium aluminum garnet, beta-SiAlON, a Mn⁴⁺ doped phosphor having formula I, a uranium-based phosphor, and blends thereof, wherein the uranium-based phosphor has formula II, III, IV, V or VI:
Aₓ[MF_{y}]:Mn⁴⁺ (I)
wherein A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7;
[Ba_{1-a-b}SrₐCa_{b}]ₓ[Mg,Zn]_{y}(UO₂)_{z}([P,V]O₄)_{2(x+y+z)/3} II
[Ba_{1-a-b}SrₐCa_{b}]ₚ(UO₂)_{q}[P,V]ᵣO_{(2p+2q+5r)/2} III
A₂UO₂[P,V]₂O₇ IV
A₄UO₂([P,V]O₄)₂ V
AUO₂([P,V]O₃)₃ VI
wherein 0≤a≤1, 0≤b≤1, 0.75≤x≤1.25, 0.75≤y≤1.25, 0.75≤z≤1.25, 2.5≤p≤3.5, 1.75≤q≤2.25, 3.5≤r≤4.5 and A is Li, Na, K, Rb, Cs or a combination thereof.

4. The device according to claim 3, wherein the Mn⁴⁺ phosphor of formula I is K₂SiF₆:Mn⁴⁺ or Na₂[SiF₆]:Mn⁴⁺.

5. An article comprising the device according to claim 1, wherein the article is selected from the group consisting of an illumination device, a lighting apparatus, a display apparatus, a backlight apparatus, a television, a mobile phone, a computer monitor, a laptop, a tablet computer, an automotive display, a self-emissive display, a transparent display, a windshield, an automotive light, an automotive tail-light, and combinations thereof.

6. The device according to claim 1, wherein when light from the LED light source travels through the color conversion layer, a first portion of light is absorbed by the color conversion layer, and a second portion of light exits the second side of the color conversion layer and contacts the substrate which reflects a portion of the second portion of light toward the color conversion layer.

7. A device comprising:
a color conversion layer comprising luminescent material, the color conversion layer having a first side and a second side;
a substrate having a first side;
the second side of the color conversion layer located on the first side of the substrate;
an LED light source located remotely from the color conversion layer, wherein the LED light source is optically coupled and/or radiationally connected to at least the first side of the color conversion layer; and
wherein the device comprises a reflective layer located between the substrate and the color conversion layer.

8. The device according to claim 7, wherein the color conversion layer comprises one film or at least two films having different refractive indices.

9. The device according to claim 8, wherein the luminescent material comprises phosphor material selected from yttrium aluminum garnet, beta-SiAlON, a Mn⁴⁺ doped phosphor having formula I, a uranium-based phosphor, and blends thereof, wherein the uranium-based phosphor has formula II, III, IV, V or VI:
Aₓ[MF_{y}]:Mn⁴⁺ (I)
wherein A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7;
[Ba_{1-a-b}SrₐCa_{b}]ₓ[Mg,Zn]_{y}(UO₂)_{z}([P,V]O₄)_{2(x+y+z)/3} II
[Ba_{1-a-b}SrₐCa_{b}]ₚ(UO₂)_{q}[P,V]ᵣO_{(2p+2q+5r)/2} III
A₂UO₂[P,V]₂O₇ IV
A₄UO₂([P,V]O₄)₂ V
AUO₂([P,V]O₃)₃ VI
wherein 0≤a≤1, 0≤b≤1, 0.75≤x≤1.25, 0.75≤y≤1.25, 0.75≤z≤1.25, 2.5≤p≤3.5, 1.75≤q≤2.25, 3.5≤r≤4.5 and A is Li, Na, K, Rb, Cs or a combination thereof.

10. The device according to claim 9, wherein the Mn⁴⁺ phosphor of formula I is K₂SiF₆:Mn⁴⁺ or Na₂[SiF₆]:Mn⁴⁺.

11. An article comprising the device according to claim 6, wherein the article is selected from the group consisting of an illumination device, a lighting apparatus, a display apparatus, a backlight apparatus, a television, a mobile phone, a computer monitor, a laptop, a tablet computer, an automotive display, a self-emissive display, a transparent display, a windshield, an automotive light, an automotive tail-light, and combinations thereof.

12. The device according to claim 7, wherein when light from the LED light source travels through the color conversion layer, a first portion of light is absorbed by the color conversion layer, and a second portion of light exits the second side of the color conversion layer and contacts the reflective layer which reflects a portion of the second portion of light toward the color conversion layer.

13. A device comprising:
a color conversion layer comprising luminescent material, the color conversion layer having a first side and a second side;
a substrate having a first side and a second side;
the second side of the color conversion layer located on the first side of the substrate;
a back reflective layer located on the second side of the substrate; and
an LED light source located remotely from the color conversion layer, wherein the LED light source is optically coupled and/or radiationally connected to at least the first side of the color conversion layer.

14. The device according to claim 13, wherein the color conversion layer comprises one film or at least two films having different refractive indices.

15. The device according to claim 13, wherein the luminescent material comprises phosphor material selected from yttrium aluminum garnet, beta-SiAlON, a Mn⁴⁺ doped phosphor having formula I, a uranium-based phosphor, and blends thereof, wherein the uranium-based phosphor has formula II, III, IV, V or VI:
Aₓ[MF_{y}]:Mn⁴⁺ (I)
wherein A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7;
[Ba_{1-a-b}SrₐCa_{b}]ₓ[Mg,Zn]_{y}(UO₂)_{z}([P,V]O₄)_{2(x+y+z)/3} II
[Ba_{1-a-b}SrₐCa_{b}]ₚ(UO₂)_{q}[P,V]ᵣO_{(2p+2q+5r)/2} III
A₂UO₂[P,V]₂O₇ IV
A₄UO₂([P,V]O₄)₂ V
AUO₂([P,V]O₃)₃ VI
wherein 0≤a≤1, 0≤b≤1, 0.75≤x≤1.25, 0.75≤y≤1.25, 0.75≤z≤1.25, 2.5≤p≤3.5, 1.75≤q≤2.25, 3.5≤r≤4.5 and A is Li, Na, K, Rb, Cs or a combination thereof.

16. The device according to claim 15, wherein the Mn⁴⁺ phosphor of formula I is K₂SiF₆:Mn⁴⁺ or Na₂[SiF₆]:Mn⁴⁺.

17. An article comprising the device according to claim 13, wherein the article is selected from the group consisting of an illumination device, a lighting apparatus, a display apparatus, a backlight apparatus, a television, a mobile phone, a computer monitor, a laptop, a tablet computer, an automotive display, a self-emissive display, a transparent display, a windshield, an automotive light, an automotive tail-light, and combinations thereof.

18. The device according to claim 13, wherein when light from the LED light source travels through the color conversion layer, a first portion of light is absorbed by the color conversion layer, a second portion of light exits the second side of the color conversion layer, travels through the substrate and contacts the back reflective layer which reflects a portion of the second portion of light toward the color conversion layer.

19. A device comprising:
a color conversion layer comprising luminescent material, the color conversion layer having a first side and a second side;
a substrate having a first side;
the second side of the color conversion layer located on the first side of the substrate; and
an LED light source located remotely from the color conversion layer, wherein the LED light source is optically coupled and/or radiationally connected to at least the first side of the color conversion layer,
wherein the color conversion layer comprises at least two films having different refractive indices, and
wherein the device comprises at least one of:
(a) the substrate has a reflectivity of at least 20%,
(b) a reflective layer located between the substrate and the color conversion layer, or
(c) a back reflective layer located on the second side of the substrate.

20. The device according to claim 19, wherein the luminescent material comprises phosphor material selected from yttrium aluminum garnet, beta-SiAlON, a Mn⁴⁺ doped phosphor having formula I, a uranium-based phosphor, and blends thereof, wherein the uranium-based phosphor has formula II, III, IV, V or VI:
Aₓ[MF_{y}]:Mn⁴⁺ (I)
wherein A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7;
[Ba_{1-a-b}SrₐCa_{b}]ₓ[Mg,Zn]_{y}(UO₂)_{z}[P,V]O₄)_{2(x+y+z)/3} II
[Ba_{1-a-b}SrₐCa_{b}]ₚ(UO₂)_{q}[P,V]ᵣO_{(2p+2q+5r)/2} III
A₂UO₂[P,V]₂O₇ IV
A₄UO₂([P,V]O₄)₂ V
AUO₂([P,V]O₃)₃ VI
wherein 0≤a≤1, 0≤b≤1, 0.75≤x≤1.25, 0.75≤y≤1.25, 0.75≤z≤1.25, 2.5≤p≤3.5, 1.75≤q≤2.25, 3.5≤r≤4.5 and A is Li, Na, K, Rb, Cs or a combination thereof.

21. The device according to claim 20, wherein the Mn⁴⁺ phosphor of formula I is K₂SiF₆:Mn⁴⁺ or Na₂[SiF₆]:Mn⁴⁺.

22. An article comprising the device according to claim 19, wherein the article is selected from the group consisting of an illumination device, a lighting apparatus, a display apparatus, a backlight apparatus, a television, a mobile phone, a computer monitor, a laptop, a tablet computer, an automotive display, a self-emissive display, a transparent display, a windshield, an automotive light, an automotive tail-light, and combinations thereof.

23. The device according to claim 19, wherein the at least two films comprise a first film having a refractive index of less than 1.52 and a second film having a refractive index of greater than 1.6.

24. The device according to claim 23, wherein when light from the LED light source travels through the color conversion layer, a first portion of the light is absorbed by first film, a second portion of the light passes through the first film and contacts the second film, and a portion of the second portion of the light is reflected toward the first film due to the difference in the refractive indices of the first film and the second film.

25. The device according to claim 19, wherein a first film of the at least two films is formed by depositing a first ink composition on the substrate or the reflective layer and curing the first ink composition to form the first film.

26. The device according to claim 25, wherein a second film of the at least two films is formed by depositing a second ink composition on the first film and curing the ink composition to form the second film.

27. The device according to claim 26, wherein the first ink composition has a first refractive index and the second ink composition has a second refractive index, wherein the first refractive index and the second refractive index are different.

28. An automotive tail-light including:
a plurality of LED light sources;
a color conversion layer comprising luminescent material, the color conversion layer having a first side and a second side;
a substrate having a first side; and
the second side of the color conversion layer located on the first side of the substrate,
the plurality of LED light sources located remotely from the color conversion layer, wherein the LED light source is optically coupled and/or radiationally connected to at least the first side of the color conversion layer,
wherein the automotive tail-light comprises at least one of:
(a) the substrate has a reflectivity of at least 20%,
(b) a reflective layer is located between the substrate and the color conversion layer, or
(c) a back reflective layer located on the second side of the substrate.

29. The automotive tail-light of claim 28, wherein the color conversion layer comprises one film or at least two films having different refractive indices.

30. The device according to claim 28, wherein the luminescent material comprises phosphor material selected from yttrium aluminum garnet, beta-SiAlON, a Mn⁴⁺ doped phosphor having formula I, a uranium-based phosphor, and blends thereof, wherein the uranium-based phosphor has formula II, III, IV, V or VI:
Aₓ[MF_{y}]:Mn⁴⁺ (I)
wherein A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7;
[Ba_{1-a-b}SrₐCa_{b}]ₓ[Mg,Zn]_{y}(UO₂)_{z}([P,V]O₄)_{2(x+y+z)/3} II
[Ba_{1-a-b}SrₐCa_{b}]ₚ(UO₂)_{q}[P,V]ᵣO_{(2p+2q+5r)/2} III
A₂UO₂[P,V]₂O₇ IV
A₄UO₂([P,V]O₄)₂ V
AUO₂([P,V]O₃)₃ VI
wherein 0≤a≤1, 0≤b≤1, 0.75≤x≤1.25, 0.75≤y≤1.25, 0.75≤y≤1.25, 2.5≤p≤3.5, 1.75≤q≤2.25, 3.5≤r≤4.5 and A is Li, Na, K, Rb, Cs or a combination thereof.
